(19) United States
(12) Patent Application Publication
(10) Pub. No.: US 2011/0094556 A1
(43) Pub. Date: Apr. 28, 2011

(54) PLANAR THERMOELECTRIC GENERATOR

(75) Inventor: Ingo Stark, Riverside, CA (US)

(73) Assignee: DIGITAL ANGEL CORPORATION, St. Paul (MN)

(21) Appl. No.: 12/605,370

(22) Filed: Oct. 25, 2009

(51) Int. Cl. H01L 35/30; H01L 35/34

(52) U.S. Cl. 136/205; 438/55; 136/201

(57) ABSTRACT

A thermoelectric generator may comprise a pair of thermally conducive top and bottom plates having a foil assembly positioned therebetween. The foil assembly may comprise a substrate having a series of alternating thermoelectric legs formed thereon. The thermoelectric legs may be formed of alternating dissimilar materials arranged in at least one row. Each one of the thermoelectric legs may define a leg axis oriented in non-parallel relation to the row axis. Thermally conductive strips mounted on opposite sides of the substrate may be aligned with opposite ends of the thermoelectric legs in the rows such that one end of the thermoelectric legs is in thermal contact with the top plate and the opposite end of the thermoelectric legs is in thermal contact with the bottom plate. The thermally conductive strips define thermal gaps between the thermoelectric legs and the top and bottom plates causing heat to flow lengthwise through the thermoelectric legs resulting in the generation of electrical voltage.

### CROSS-REFERENCE TO RELATED APPLICATIONS

(Not Applicable)

### STATEMENT RE: FEDERALLY SPONSORED RESEARCH/DEVELOPMENT

(Not Applicable)

### FIELD

The present disclosure relates generally to thermoelectric devices and, more particularly, to a thermoelectric generator having a planar configuration.

### BACKGROUND

Thermoelectric generators are self-sufficient energy sources that convert thermal energy into electrical energy under the Seebeck effect—a phenomenon whereby heat differences are converted into electricity due to charge carrier diffusion in a conductor. Electrical power may be generated under the Seebeck effect by utilizing thermocouples comprised of pairs of dissimilar materials. The dissimilar materials may comprise n-type and p-type thermoelectric legs joined at one end of the pair. The terms n-type and p-type refer to the negative and positive types of charge carriers within the material.

Electricity is generated due to a temperature gradient between the ends of the thermocouple. The temperature gradient may be artificially applied or it may be natural-occurring such as the waste heat that is constantly rejected by the human body. In one application for thermoelectric generators, a wrist watch is exposed to air at ambient temperature wherein the air acts as a heat sink on one side of the wrist watch. An opposite side of the wrist watch is exposed to the higher temperature of the wearer's skin which acts as the heat source. The temperature gradient that is present across the thickness of the wristwatch may be exploited whereby the thermoelectric generator may generate a supply of power sufficient to operate the wrist watch as a self-contained unit. The wrist watch is one of many microelectronic devices that require only a small amount of power and are therefore compatible for powering by a thermoelectric generator.

Often with waste heat sources, only a small temperature difference exists between the heat source and the heat sink. Because of the small temperature difference, a relatively large number of thermocouples must be connected in series in order to generate a sufficiently large thermoelectric voltage for powering any number of different devices such as, without limitation, sensor systems or devices in a micro sensor network. However, recent advances in the field of electronic circuitry have reduced the requirement for integrating a large number of thermocouples into a thermoelectric generator. More specifically, recent improvements in voltage-multiplying components such as voltage transformers, voltage multipliers and charge pumps provide a means for efficiently converting small voltages (e.g., in the range of ten millivolts up to several hundred millivolts) of a thermoelectric generator into sufficiently high voltages (e.g., in the range of one to four volts) necessary to drive the electronic devices that are normally powered by batteries.

Because the voltage generated by a thermoelectric generator is proportional to the number of thermocouples electrically connected in series, the ability to amplify a relatively low voltage provides a means for reducing the total number of thermocouples in the thermoelectric generator. The reduced number of thermocouples translates into a reduced overall size of the thermoelectric generator. Furthermore, the reduced number of thermocouples and the smaller physical size of the thermoelectric generator results in a reduction in the overall cost of the thermoelectric generator. Furthermore, because the voltage of a thermocouple is proportional to the temperature gradient acting across the thermocouple, the use of advanced electronics to amplify the voltage provides a means for exploiting smaller temperature gradients. The ability to generate sufficiently high voltages from small temperature gradients has the effect of increasing the number of different applications for which thermoelectric generators may be employed.

Thermoelectric generators and other thermoelectric structures may be configured in a number of different arrangements. For example, heat flux sensors are a type of thermoelectric structure which may be provided in an in-plane configuration. In an in-plane configuration, the thermoelectric legs are formed on a substrate wherein electrical current flows lengthwise through the thermoelectric legs along a direction that is parallel to the substrate surface. In heat flux sensors, it is desirable to form the thermoelectric legs as a thin film of relatively small thickness in order to minimize the thermal capacitance (i.e., thermal mass) of the thermoelectric legs which increases the response time for the heat flux sensor. Furthermore, a heat flux sensor preferably has minimal thermal resistance in order to minimize the influence on the heat flux and to minimize the temperature drop across the sensor.

In contrast, thermoelectric generators preferably have a large thermal resistance in order to increase the temperature drop across the thermoelectric generator. The thickness of the thermoelectric legs of a thermoelectric generator in an in-plane configuration is preferably large in order to minimize the electrical resistance which translates into a relatively higher power output.

However, one of the drawbacks associated with relatively thick thermoelectric legs and other films formed on substrate material is the internal stresses that develop during the process of forming the thermoelectric legs and other films on the substrate. The internal stresses may be caused by differences in the thermal expansion coefficients of the thermoelectric material relative to the substrate material. Although the thermal expansion coefficients of semiconductor legs may be compatible with the substrate at room temperature, at elevated temperatures of up to 300° C., the thermal expansion coefficients of films may be mismatched with the substrate. For example, at room temperature, polyimide substrate such as Kapton® has a thermal expansion coefficient α of 20×10⁻⁶ K⁻¹ which is in the same order of magnitude as the thermal expansion coefficient of Bi₂Te₃-type semiconductor materials such as Bi_{0.5}Sb_{1.5}Te₃ semiconductor material which has a thermal expansion coefficient α of 20.1×10⁻⁶ K⁻¹. The thermal expansion coefficient for metal films is also compatible with the thermal expansion coefficient of polyimide substrate at room temperature. For example, aluminum (Al) has a thermal expansion coefficient α of 23.1×10⁻⁶ K⁻¹, nickel (Ni) has a thermal expansion coefficient α of 12.8×10⁻⁶ K⁻¹, gold (Au) has a thermal expansion coefficient α of 14.3×10⁻⁶ K⁻¹ and silver (Ag) has a thermal expansion coefficient α of 19.7×10⁻⁶ K⁻¹.

However, at elevated temperatures, the thermal expansion coefficient of polyimide substrate (e.g., Kapton®) increases significantly. For example, for temperatures in the range of 100° C. to 200° C., polyimide has a thermal expansion coefficient α of 31×10⁻⁶ K⁻¹. For temperatures in the range of 200° C. to 300° C., polyimide has a thermal expansion coefficient α of 48×10⁻⁶K⁻¹. As can be seen, the elevated temperatures at which the thin films are formed and processed on the polyimide substrate results in a mismatch between the linear expansion coefficients of the materials. In this regard, cooling of the heated substrate following the deposition of a Bi₂Te₃-type semiconductor from elevated temperatures may result in the buildup of internal stresses in the thin films. Likewise, heating of thin film structures on the polyimide substrate during the annealing process may also result in the buildup of internal stresses in the thin films which may manifest as defects and/or damage in the thin film.

Included in the prior art are several thermoelectric structures having an in-plane configuration. For example, U.S. Pat. No. 6,278,051 to Peabody discloses a heat flux sensor having a plurality of links or thermoelectric legs. The legs are electrically connected in series by metal links that are formed on top of the ends of the legs. The combination of legs and metal links are deposited on a metallic substrate. In this regard, the Peabody device discloses an in-plane arrangement wherein heat flows through the legs along a direction that is parallel to the substrate. However, Peabody is not understood to disclose an arrangement wherein the legs are configured to minimize the formation of internal stresses in the legs that may occur as a result of the fabrication process. Furthermore, the heat sensor of Peabody discloses that the legs are formed of metallic material such as copper-nickel and the substrate is highly thermally conductive (i.e., anodized aluminum). In addition, Peabody discloses that thermal gaps in the heat flux sensor are filled with a polymeric insulating material such that the sensor is effectively embedded is a solid mass of polymer. Additionally, the heat flux sensor of Peabody has a relatively low thermal resistance of approximately 1.2 cm² K/W because the path along which heat flows is primarily metallic. In comparison, a thermoelectric generator as described herein may have a thermal resistance of approximately 19 cm² K/W. Finally, the Peabody sensor has relatively low sensitivity (e.g., approximately 80 mV/(W/cm²)) as compared to a higher sensitivity (e.g., approximately 2000 mV/(W/cm²)) as may be desired in a thermoelectric device.

U.S. Pat. No. 4,029,521 to Korn et al. discloses a thermopile having a plurality of thermocouple junctions deposited on a substrate and arranged in series. Korn discloses a plurality of thin coatings of about 1 micron thickness and formed of dissimilar materials in rows on a substrate to form a plurality of hot and cold thermocouple junctions. Korn indicates that the thermocouples are used for the detection and measurement of electromagnetic radiation such as in the infrared range. Korn further discloses a heat sink disposed near the cold junctions and separated from the hot junctions by a tunnel or other thermally insulating means. Korn only disclose a heat sink (i.e., heat couple plate) on the bottom side of the device because the top side of the device is open to thermal radiation. However, Korn discloses that the legs in each row are arranged in generally parallel relation to the row such that Korn is not understood to accommodate differences in thermal expansion coefficients of the materials that make up the Korn device.

U.S. Pat. No. 4,049,469 to Kolomoets et al. discloses an in-plane thermoelement having films of semiconductor material formed on both sides of a substrate. The semiconductor material on the top and bottom sides of the substrate is electrically connected through holes formed in the substrate. The semiconductor material is in contact with a cold plate on one side by means of strips of a heat-conducting material. Likewise, the semiconductor material is in contact with a hot plate on an opposite side by means of the strips of heat-conducting material. Heat flows through the semiconductor material along a direction that is parallel to the substrate. The strips of heat-conducting material are disposed in spaced relation to one another to form gaps. The gaps between the strips may be filled with a gas. The strips are indicated as having a high thermal and electrical conductivity and may be formed of silver, copper or aluminum. However, nowhere does Kolomoets indicate that the semiconductor material on the substrate is arranged to minimize internal stresses by accommodating differences in thermal expansion coefficients of the semiconductor materials and substrate that make up the Kolomoets device.

U.S. Pat. No. 6,204,502 to Guilmain et al. discloses an in-plane thermal sensor having a substrate formed of flexible material such as Kapton®. The substrate includes a succession of thermocouple elements forming a continuous track or row of alternating copper/constantin to form a plurality of thermocouple junctions. However, each one of the thermocouple elements of Guilmain is understood to be arranged in parallel to the row. In this regard, Guilmain is not understood to provide an arrangement that accommodates the differences in the thermal expansion coefficients of the copper/constantin and the substrate that makes up the Guilmain sensor.

U.S. Pat. No. 3,293,082 to Brouwer et al. disclose an in-plane thermal sensor formed of a series of strips of alternating dissimilar materials to form a plurality of thermocouples on a substrate. The substrate is disclosed as being comprised of electrically insulating material. Certain ones of the junctions are exposed to radiation on a top side of the device. On a bottom side of the device, certain junction are in thermal contact with a bottom heat couple plate comprised of a metal body having a high thermal capacity such as copper, aluminum or silver. However, because the series of strips of alternating dissimilar materials are formed in parallel arrangement to one another on the substrate, Brouwer is not understood to provide a means for accommodating differences in the thermal expansion coefficients of the strips and the substrate that make up the Brouwer sensor.

U.S. Patent Publication No. 20040075167 to Nurnus et al. discloses in claim 1 an in-plane configuration of a thermoelectric element having at least one pair of semiconductor components formed on a substrate or, alternatively, on semiconductor component paired with a metal film formed on the substrate. Nurnus discloses that a diffusion barrier formed of nickel, chromium, aluminum or other material may be deposited in a thickness of 10 nm to 10 microns on the substrate. Nurnus also discloses that metal contacts for interconnecting the pair of semiconductor components may be formed of gold, bismuth, nickel, silver, or of bismuth/tin/lead/cadmium eutectics. However, Nurnus is not understood to disclose that the pair of semiconductor components or the semiconductor component paired with the metal film is arranged in a manner to accommodate differences in thermal expansion coefficients relative to the substrate.

As can be seen, there exists a need in the art for a thermoelectric generator and method of fabrication which minimizes the formation of internal stresses in the thermoelectric legs deposited on the substrate. In this regard, there exists a need in the art for a system and method for fabricating a thermoelectric generator which minimizes the formation of defects and/or damage in the thermoelectric film during the fabrication process. Furthermore, there exists a need in the art for a system and method for fabricating a thermoelectric generator which facilitates the selection of variations in the geometry of the thermoelectric legs in order to match the electrical and thermal resistance of the application that is to be powered by the thermoelectric generator. In this regard, there exists a need in the art for a system and method for fabricating a thermoelectric generator which provides a means for tailoring the leg length and/or leg thickness to the heat flow and temperature gradient of the given application. Finally, there exists a need in the art for a thermoelectric generator having the above-described attributes and which is simple in construction to facilitate mass-production in a cost-effective manner.

### SUMMARY

The above-described needs associated with thermoelectric generators are specifically addressed and alleviated by the embodiments disclosed herein wherein a thermoelectric generator is provided with an in-plane configuration. The thermoelectric generator includes thermoelectric legs arranged in rows on a substrate and oriented in non-parallel relation to the row axis such that the thermoelectric legs form a meandering pattern on the substrate. The thermoelectric legs and substrate comprise a foil assembly which is sandwiched between a pair of thermally conductive heat couple plates (i.e., top and bottom plates). The foil substrate is relatively thin which minimizes internal stresses in the thermoelectric legs due to the ability of the thin foil substrate to bend and flex in response to such internal stresses as compared to a relatively stiff and rigid silicon wafer which lacks the necessary flexibility to accommodate or bend in response to internal stresses in the thermoelectric legs.

Advantageously, the meandering pattern of the thermoelectric legs also provides a means for minimizing internal stresses in thin films formed on the substrate such as metal bridges and thermoelectric legs. Such internal stresses may otherwise develop as a result of differences in the coefficient of thermal expansion of the substrate relative to the coefficient of thermal expansion of the thin films during the fabrication process. In this regard, the meandering pattern of the thermoelectric legs provides for a large number of changes in the lateral orientation of the legs within a relatively short distance along the substrate. The large number of orientation changes improves the mechanical stability of the thermoelectric legs that make up the thermocouples of the thermoelectric generator. In addition, the meandering pattern of thermoelectric legs provides a means for minimizing the length of the thermoelectric legs which further increases the mechanical stability and reliability of the thermocouples.

In an embodiment, the thermoelectric generator comprises the pair of top and bottom plates having the foil assembly interposed therebetween. The substrate of the foil assembly may comprise an electrically insulating material having a relatively low thermal conductivity. The thermoelectric legs may be formed of thermoelectric material such as semiconductor material and/or metallic material. The thermoelectric legs are arranged on the substrate as a series of legs formed of alternating dissimilar materials. For example, the thermoelectric legs may be arranged on the substrate in a pattern of alternating n-type and p-type legs formed, respectively, of n-type and p-type semiconductor materials. Alternatively, the thermoelectric legs may be arranged on the substrate in a pattern of metal legs alternating with semiconductor legs formed of one type of semiconductor material (e.g., n-type or p-type). The thermoelectric legs may be arranged in one or more rows and may be formed on one or both of the upper and lower surfaces of the substrate.

Each one of the thermoelectric legs defines a leg axis which is preferably oriented in non-parallel relation to the row axis. The thermoelectric generator may further include at least one pair of thermally conductive strips which may be positioned on opposite sides of the substrate. The thermally conductive strips may be aligned with opposite ends of the thermoelectric legs in the row such that one end of the thermoelectric legs is in thermal contact with the top plate and the opposite end of the thermoelectric legs is in thermal contact with the bottom plate. Furthermore, the thermally conductive strips define thermal gaps between the thermoelectric legs and the top and bottom plates.

The thermal gaps define areas of increased thermal resistance relative to the low thermal resistance provided by the thermally conductive strips. The thermal gaps may be filled with a gas such as, without limitation, air, nitrogen, krypton and xenon or any other suitable fluid or solid of low thermal conductivity. The thermal gaps cause heat to flow lengthwise through the thermoelectric legs. In the arrangement of the in-plane thermoelectric generator, heat flows lengthwise through the thermoelectric legs in order to produce a voltage potential across the thermoelectric legs. The generated electric current flows through the legs along a direction that is parallel to the plane of the substrate and parallel to the leg axis of each one of the thermoelectric legs. Advantageously, the relatively simple construction of the foil assembly and the means for interconnection of the foil assembly to the top and bottom heat couple plates facilitates mass-production of the thermoelectric generator in a cost-effective manner.

The features, functions and advantages that have been discussed can be achieved independently in various embodiments of the present disclosure or may be combined in yet other embodiments, further details of which can be seen with reference to the following description and drawings below.

### BRIEF DESCRIPTION OF THE DRAWINGS

These and other features of the present disclosure will become more apparent upon reference to the drawings wherein like numbers refer to like parts throughout and wherein:

FIG. 1 is a perspective illustration of a thermoelectric generator having an in-plane configuration;

FIG. 2 is a perspective exploded illustration of an embodiment of the thermoelectric generator comprising a foil assembly sandwiched between a top plate and a bottom plate and wherein the foil assembly is thermally connected to the top plate and bottom plate by thermally conductive strips;

FIG. 3 is a sectional illustration of the thermoelectric generator taken along line 3-3 of FIG. 1 and illustrating the foil assembly comprising thermoelectric legs disposed on a substrate wherein a temperature gradient across the top and bottom plates results in heat flow in a lengthwise direction through the thermoelectric legs;

FIG. 4 is a top view of the thermoelectric generator taken along line 4-4 of FIG. 3 and illustrating a series of the thermoelectric legs formed of alternating dissimilar materials and being arranged in rows on the substrate and further illustrating the alignment of the thermally conductive strips with opposite ends of the thermoelectric legs in the rows causing heat to flow lengthwise through the thermoelectric legs;

FIG. 5 is a sectional illustration of a further embodiment of the thermoelectric generator similar to the illustration of the thermoelectric generator of FIG. 3 and wherein the thermoelectric legs are formed on both upper and lower substrate surfaces of the substrate;

FIGS. 6A-6F are schematic top view illustrations of a process for fabricating an embodiment of the thermoelectric generator having alternating thermoelectric legs formed of n-type and p-type legs interconnected by metal bridges;

FIGS. 7A-7F are a series of schematic top view illustrations of a process of fabricating a further embodiment of the thermoelectric generator wherein the series of thermoelectric legs comprise metal legs alternating with n-type or p-type thermoelectric legs;

FIG. 7G is a sectional illustration of the thermoelectric generator taken along line 7G-7G of FIG. 7F and illustrating the metal legs being formed on the substrate and the leg ends of the semiconductor legs overlapping the leg ends of the metal legs and being electrically coupled thereto and further illustrating an electrically insulating layer interposed between the metal legs and the semiconductor legs;

FIGS. 8A-8F are a series of schematic top view illustrations of a further embodiment of the thermoelectric generator wherein the thermoelectric legs are comprised of alternating metal and semiconductor legs similar to that which is illustrated in FIGS. 6A-6F and wherein the semiconductor legs are oriented in perpendicular relation to the row axis;

FIG. 9 is a flow diagram illustrating an embodiment of a process of fabricating a thermoelectric generator;

FIG. 10 is a flow diagram illustrating a further embodiment of a process of fabricating a thermoelectric generator; and

FIGS. 11-16 are plots illustrating the performance characteristics of the thermoelectric generator at varying temperature differentials between the top and bottom plates.

### DETAILED DESCRIPTION

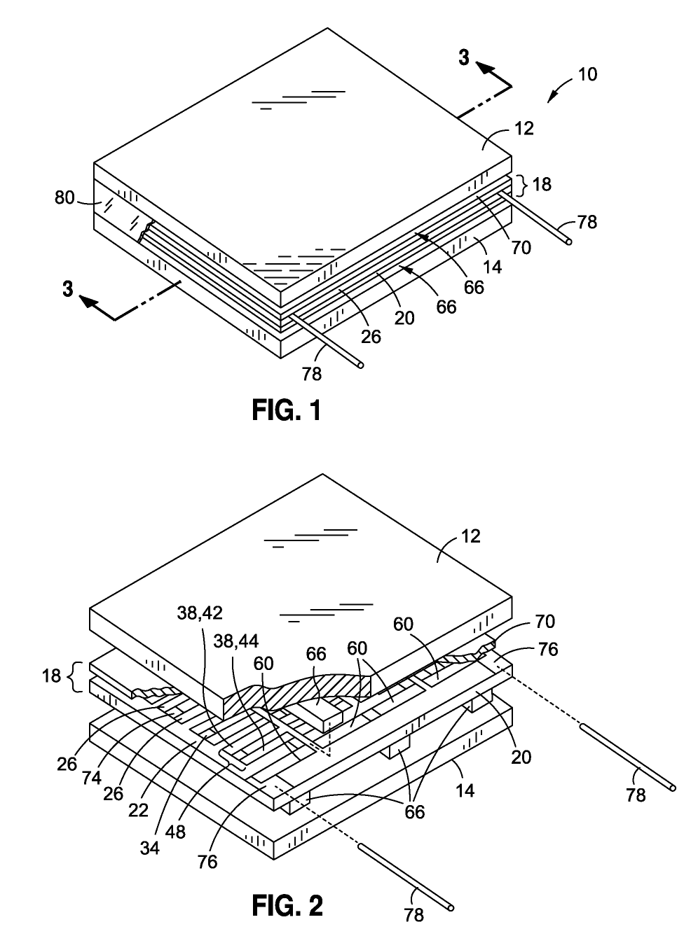

Referring now to the drawings wherein the showings are for purposes of illustrating preferred and various embodiments of the disclosure only and not for purposes of limiting the same, shown in FIG. 1 is a perspective illustration of an embodiment of a thermoelectric generator 10 having an in-plane configuration wherein the longitudinal axis of the thermoelectric legs 26 of the thermoelectric generator 10 are oriented parallel to the surface of the substrate 20 upon which the thermoelectric legs 26 are formed.

As can be seen in FIG. 2 and as will be described in greater detail below, the thermoelectric legs 26 are formed of alternating material types and are arranged in one or more rows 60. The thermoelectric legs 26 are oriented in non-parallel (e.g., perpendicular) relation to the axis of each row. Advantageously, the thermoelectric legs 26 form a meandering pattern on the substrate 20 which reduces internal stresses of the structure of the thin film which makes up the thermoelectric legs 26. Such internal stresses may result from different linear thermal expansion coefficients of the substrate 20 relative to the thermoelectric legs 26 at elevated temperatures during the fabrication process.

Advantageously, the meandering pattern of the thermoelectric legs 26 as illustrated in FIG. 2 minimizes the buildup of such internal stresses allowing for absorption of such stresses by the relatively short length of the thermoelectric legs 26 as well as by the constantly changing lateral orientation of the thermoelectric legs 26 of the meandering pattern. The net result of the meandering pattern is an increase in the mechanical stability and reliability of the foil assembly 18. In this regard, the arrangement of the thermoelectric generator 10 provides a degree of flexibility which may facilitate the mounting of the thermoelectric generator 10 to non-planar or curved surfaces.

A further advantage associated with the embodiments of the thermoelectric generator 10 as disclosed herein include the ability to tailor the geometry of the components that make up the thermoelectric generator 10 to the specific application for which the thermoelectric generator 10 is employed. For example, the length l, width w and thickness tₗ of the thermoelectric legs 26 may be configured to provide a relatively high thermal resistance in order to increase the temperature drop across the thermoelectric generator 10 (i.e., across the top and bottom plates 12, 14).

The in-plane thermoelectric generator 10 may be provided in an embodiment wherein the thermoelectric legs 26 have a generally large thickness in order to reduce the electrical resistance and thereby increase the power output. Because the voltage generated by the thermoelectric generator 10 is proportional to the temperature gradient acting across the series of thermocouples 48 formed by the adjacent pairs of thermoelectric legs 26, the ability to increase the temperature drop across the thermoelectric generator 10 results in an increase in the variety of different types of applications for which the thermoelectric generator 10 may be applied.

Referring still to FIG. 2, shown is the foil assembly 18 comprising the substrate 20 having an upper substrate surface 22 upon which a series of thermoelectric legs 26 are formed. The thermoelectric legs 26 are preferably formed of alternating dissimilar materials such as dissimilar semiconductor materials (i.e., n-type and p-type legs 42, 44). Alternatively, the alternating dissimilar materials that make up the thermoelectric legs 26 may be formed of semiconductor material 38 alternating with thermoelectric legs 26 formed of metallic material 34.

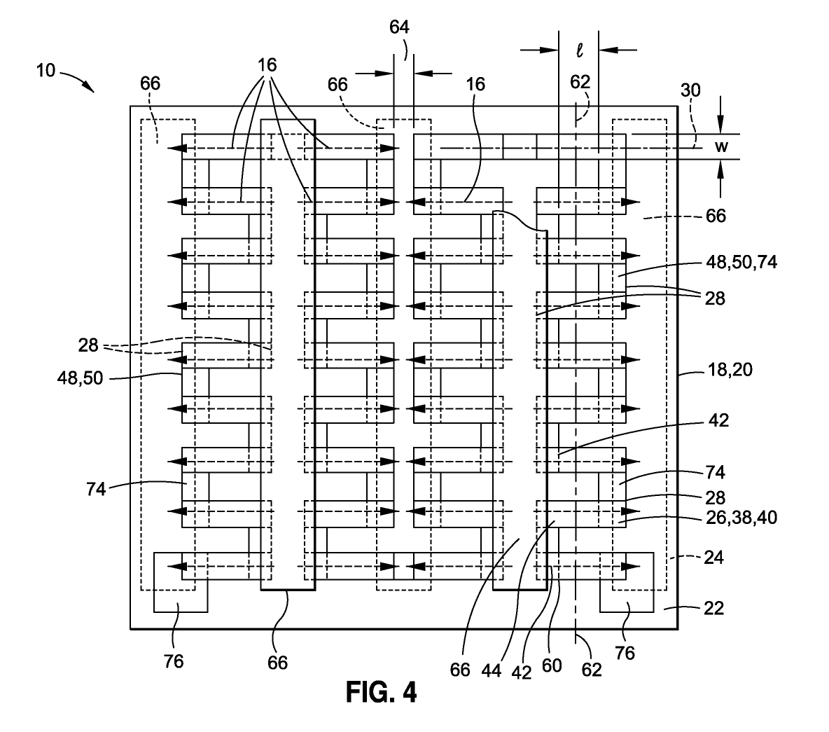

As can be seen in FIG. 2, the foil assembly 18 is located between the top and bottom plates 12, 14. The top and bottom plates 12, 14 are thermally connected to the thermoelectric legs 26 by means of one or more thermally conductive strips 66 which may be aligned with the opposing ends of the thermoelectric legs 26 in each row. The thermoelectric legs 26 may be electrically insulated from the top plate 12 by means of an electrically insulating layer 70 as illustrated in FIG. 2. The substrate 20 is preferably formed of an electrically insulating material such that the thermoelectric legs 26 are electrically insulated from the bottom plate. As can be seen, the bottom plate 14 is in thermal contact with the bottom surface of the substrate 20 by means of one or more of the thermally conductive strips 66. For example, the thermoelectric generator 10 shown in FIG. 2 includes three of the thermally conductive strips 66 in alignment with the leg ends 28 of the four rows 60 of thermoelectric legs 26. As best seen in FIG. 4, the middle thermally conductive strip 66 in contact with the bottom plate 14 serves as a thermal conduit for the middle two rows 60 of thermoelectric legs 26. The outer two thermally conductive strips 66 each serve as the thermal conduit for the outermost rows 60 of thermoelectric legs 26.

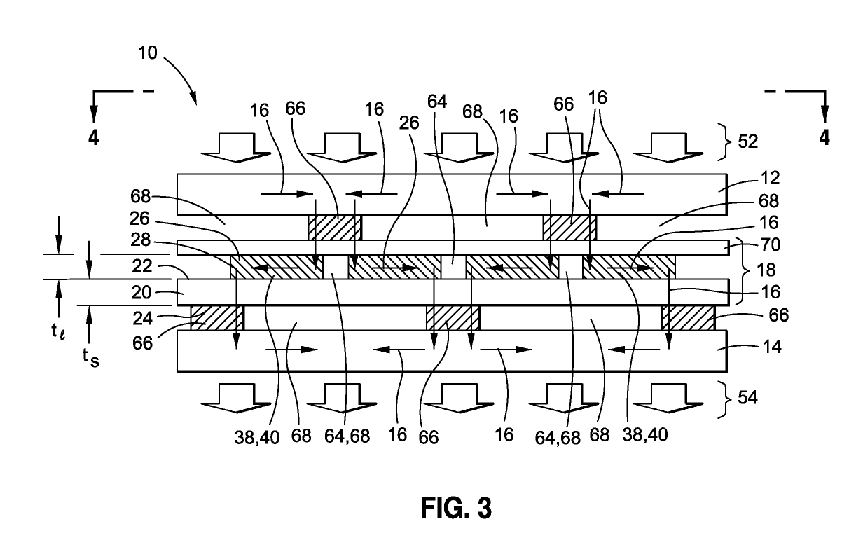

Referring to FIG. 3, shown are the locations of the thermally conductive strips 66 which can be seen as being generally aligned with opposite ends of the thermoelectric legs 26 in an adjacent pair of rows 60. The thermally conductive strips 66 are specifically arranged in order to facilitate the flow of heat from one heat couple plate through the foil assembly 18 and into the opposing top and bottom plate 12, 14. The thermally conductive strips 66 located adjacent the top plate 12 are arranged in alignment with the ends of the thermoelectric legs 26 of an adjacent pair of rows 60 while the thermally conductive strips 66 that are located adjacent the bottom plate 14 are aligned with the opposite leg ends 28 of the thermoelectric legs 26 in an adjacent pair of rows 60. Notably, the thermally conductive strips 66 are arranged in spaced relation to one another to form thermal gaps 68 which serve as areas of high thermal resistance causing a majority of the heat to flow through the thermoelectric legs 26. In this manner, the thermally conductive strips 66 are placed in thermal contact with the opposite leg ends 28 of each one of the thermoelectric legs 26 such that heat flows along the heat flow direction 16 indicated by the arrows in FIG. 3. In this regard, heat flows lengthwise through each one of the thermoelectric legs 26 in order to produce a voltage potential across the thermoelectric legs 26.

It should be noted that although FIG. 3 illustrates the top plate 12 as the heat source 52 and the bottom plate 14 as the heat sink 54 wherein heat flows from top to bottom, the thermoelectric generator 10 may operate in either direction of heat flow. For example, heat may flow from the bottom plate 14 toward the top plate 12 in a direction that is the reverse of that which is shown by the arrows in FIG. 3. In this regard, due to its symmetric configuration, the thermoelectric generator 10 generates electricity regardless of the direction of heat flow.

Referring to FIG. 4, shown is a top view of the thermoelectric generator 10 illustrating the direction of heat flow from the thermally conductive strips 66 through the thermoelectric legs 26. As can be seen, the thermoelectric legs 26 are arranged as a series of alternating thermoelectric legs 26 of dissimilar materials. For example, the thermoelectric legs 26 may alternate from different types of semiconductor materials such as n-type and p-type legs 42, 44. The substrate 20 is preferably formed of an electrically insulating material which preferably has a relatively low thermal conductivity. For example, in a preferred embodiment, the substrate 20 may be formed of polyimide material such as Kapton® commercially available from E. I. duPont de Nemours & Co., Inc. However, the substrate 20 may be formed of any suitable material having a relatively low thermal conductivity and which is preferably electrically insulating.

The substrate 20 may be provided in any suitable substrate thickness tₛ including, but not limited to, a substrate thickness tₛ in the range of from 5 microns to 100 microns. Preferably, the substrate 20 such as polyimide film is provided in a substrate thickness tₛ of 7.5 microns although 12.5 microns may also be a suitable substrate thickness tₛ. The substrate 20 is preferably formed of a material that is mechanically stable at the elevated temperatures associated with deposition of semiconductor films and with the annealing procedure. Furthermore, the substrate 20 is preferably a relatively thin material having dimensional stability and which is resistant against chemicals such as acids commonly used in the process for structuring the thermoelectric legs 26 following deposition thereof on the substrate 20.

Referring to FIG. 3, the thermoelectric legs 26 are preferably provided in a thickness which is compatible with the substrate 20 material as well as with the application for which the thermoelectric generator 10 is employed. For example, thermoelectric legs 26 may be formed of semiconductor material 38 in a leg thickness tₛ range of from 15 microns up to approximately 100 microns or more and, preferably, in a thickness tₛ of approximately 25 microns.

As indicated above, thermoelectric generators differ in their construction from heat sensors in that thermoelectric generators are preferably configured to have a high thermal resistance in order to maximize the temperature difference across the thermoelectric generator. Furthermore, the thermoelectric legs of an in-plane thermoelectric generator preferably have a relatively large leg thickness tᵢ relative to the substrate thickness tₛ in order to minimize electrical resistance and thereby increase the power output. In this regard, the configuration of thermoelectric generators for producing electricity is generally opposite to the configuration of heat flux sensors. For example, heat flux sensors typically include thermoelectric legs of relatively small thickness in order to increase the response time of the heat flux sensor by minimizing the thermal capacity (i.e., thermal mass) of the thermoelectric legs.

Referring to FIGS. 3-4, the geometry of the thermoelectric legs 26 such as the leg length l may be sized to maximize power output. In this regard, the leg length l of the thermoelectric legs 26 may be in the range of from 50 microns to 500 microns although the leg length l may be provided in any range. As indicated earlier, the thermoelectric legs 26 are preferably provided in a relatively short length in order to increase the power output. However, the selection of the leg length may be based upon the thermal resistance of a relatively short leg length in consideration of the temperature drop across the thermoelectric leg 26 as a result of other resistances in series and/or parallel with the thermoelectric leg 26.

Advantageously, the in-plane configuration of the thermoelectric generator 10 as disclosed herein facilitates the implementation of a relatively wide range of leg lengths as compared to a cross-plane configuration of a thermoelectric generator wherein adjustability of the leg length is limited in the ability to build up the thickness (i.e., leg length) along a direction normal to the substrate 20. The ability to vary the leg lengths facilitates tailoring the performance of the thermoelectric generator 10 to a given thermal environment. For example, for applications with lower available heat flow and reduced temperature gradient such as body heat applications, the thermoelectric legs 26 may be provided in a relatively long length in order to achieve higher thermal resistances. In addition, the thermoelectric legs 26 may be provided in any suitable width w such as widths in the range of from about 10 microns up to about 500 microns.

As was earlier mentioned, internal stresses in the thermoelectric legs 26 may be minimized by frequently changing the lateral orientation of the thermoelectric legs 26 and by minimizing the leg lengths. In this regard, the thickness of the thermoelectric legs 26 may be sized in relation to the leg length. The leg length may be sized in relation to the substrate thickness tₛ in consideration of internal stresses in the thermoelectric legs 26 and to increase the flexibility or bendability of the foil assembly 18. The enhanced flexibility may improve thermal contact of the thermoelectric generator 10 to a curved surface of a heat source 52 or heat sink 54. In this regard, the leg thickness tₗ of the thermoelectric legs 26 may be provided in a specific ratio relative to the substrate thickness tₛ. For example, the leg thickness tₗ may be provided in a multiple of from 1 to about 10 times the substrate thickness tₛ and, more preferably, the thermoelectric legs 26 may be provided in a leg thickness tₗ that is about 2 to 4 times the thickness of the substrate 20. However, the thermoelectric legs 26 may be provided in any leg thickness tₗ relative to the substrate thickness tₛ.

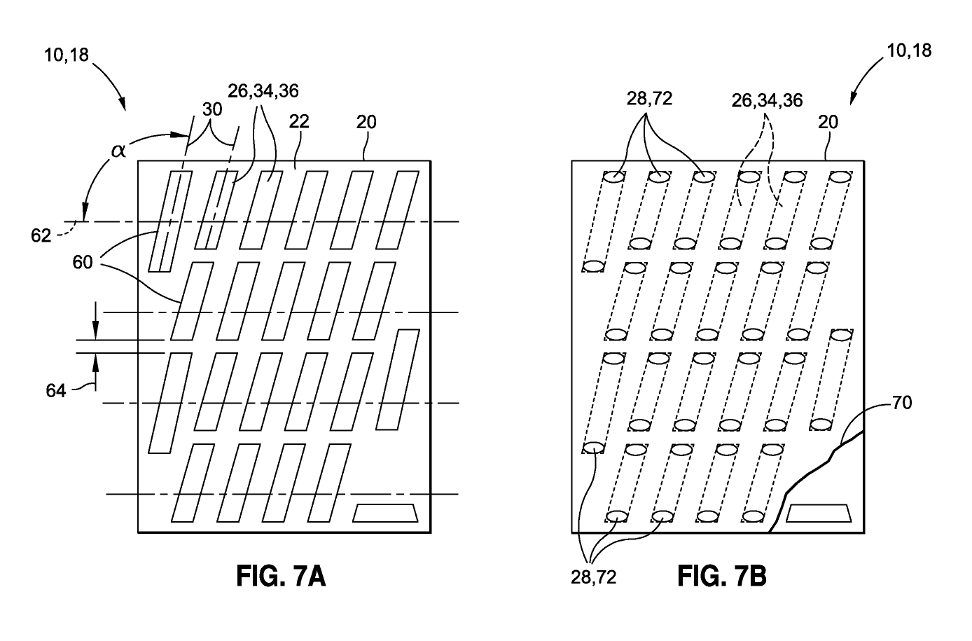

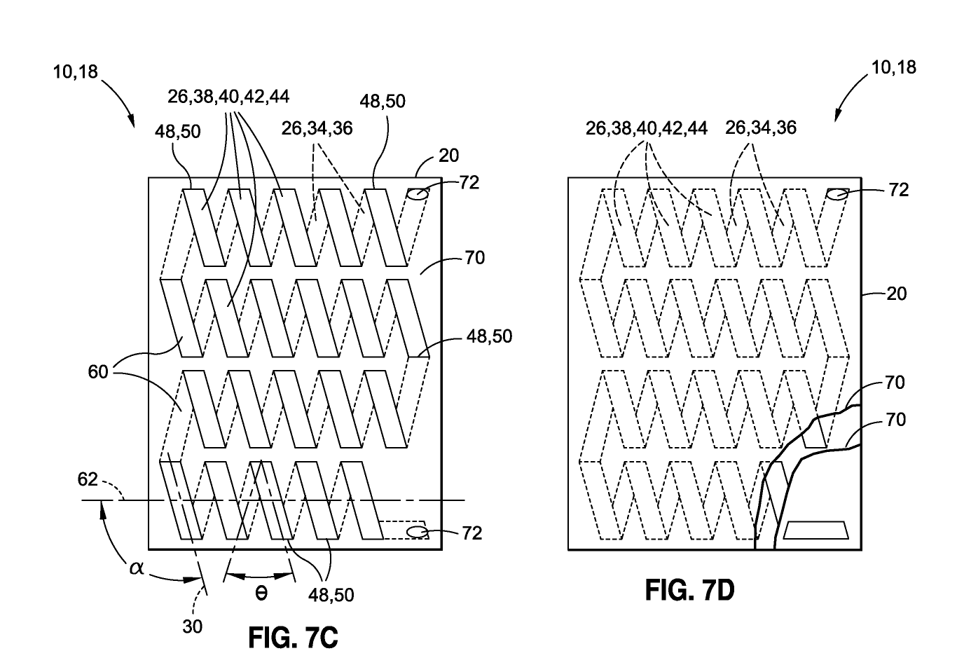

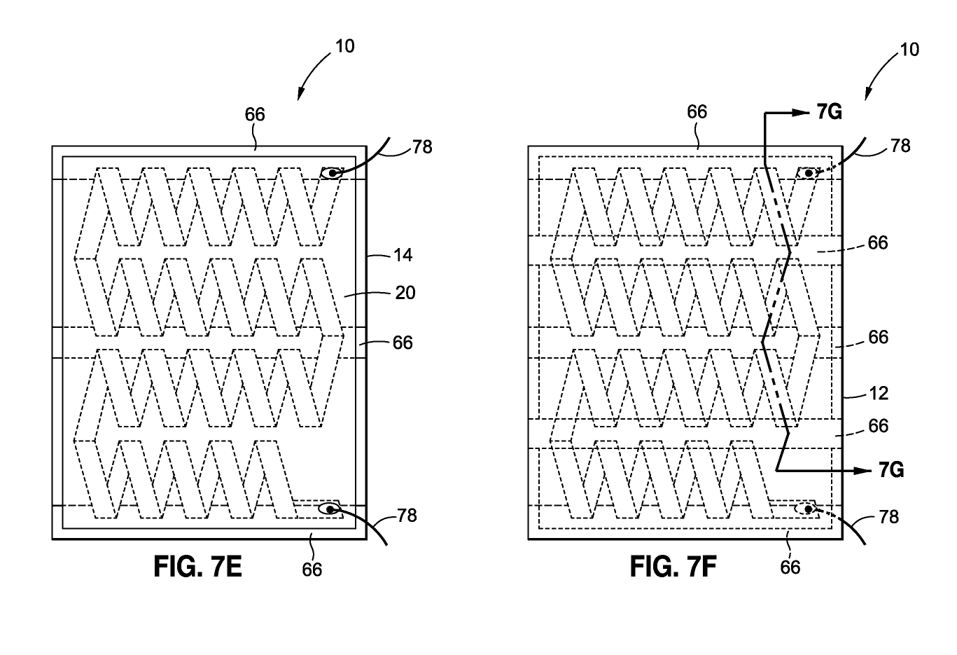

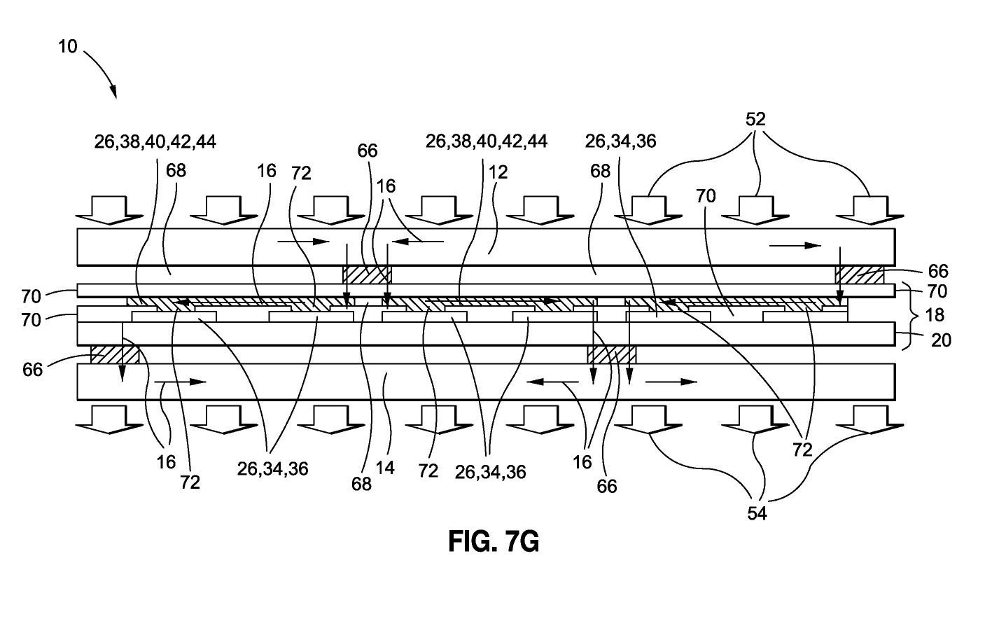

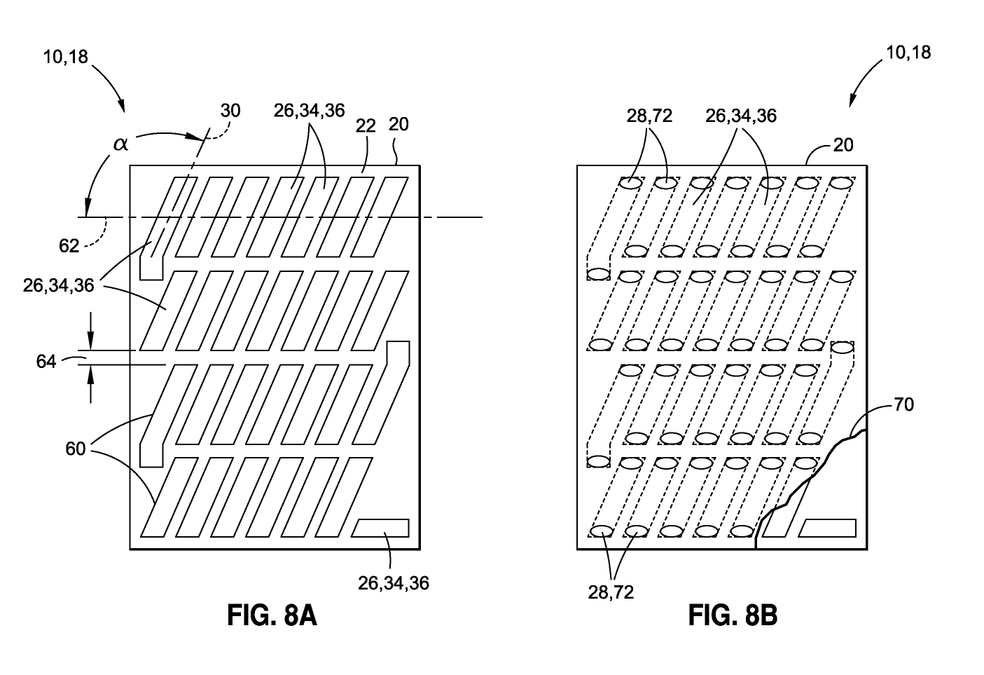

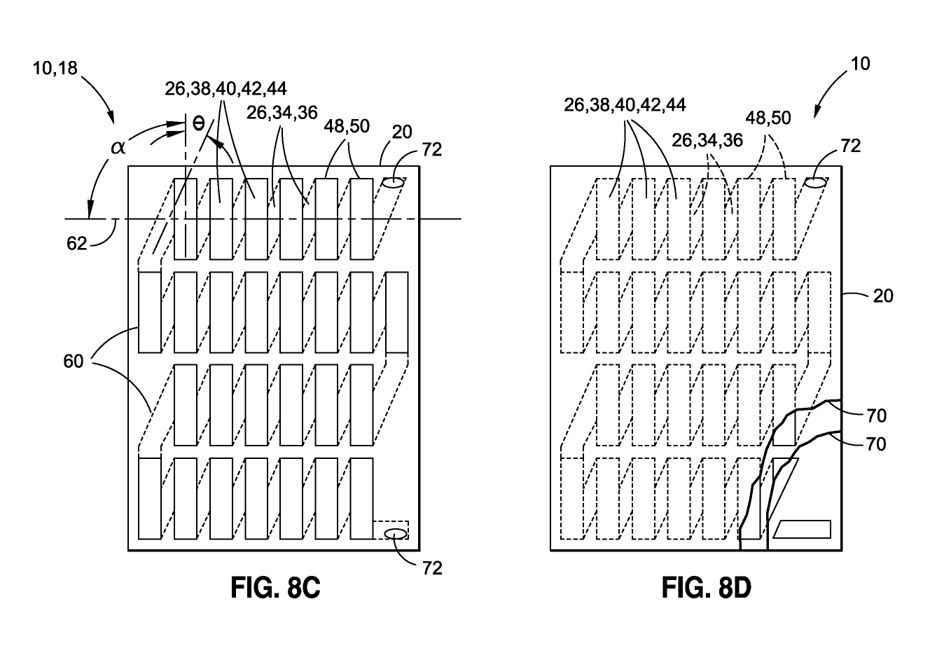

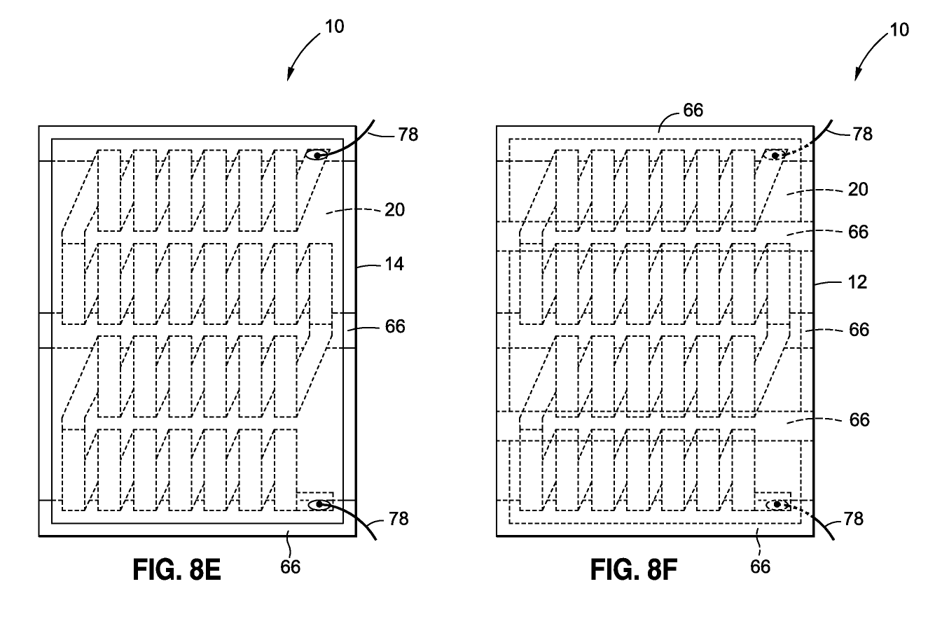

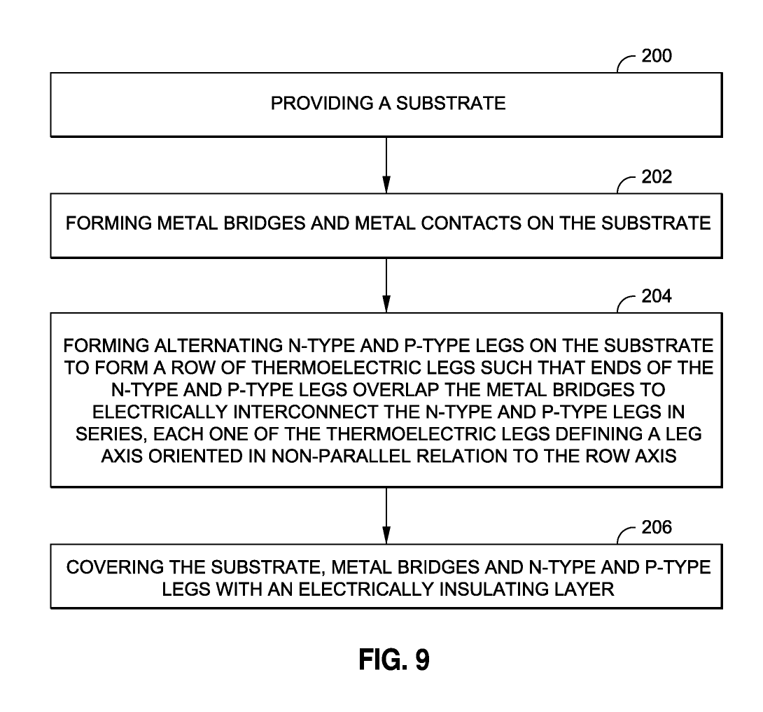

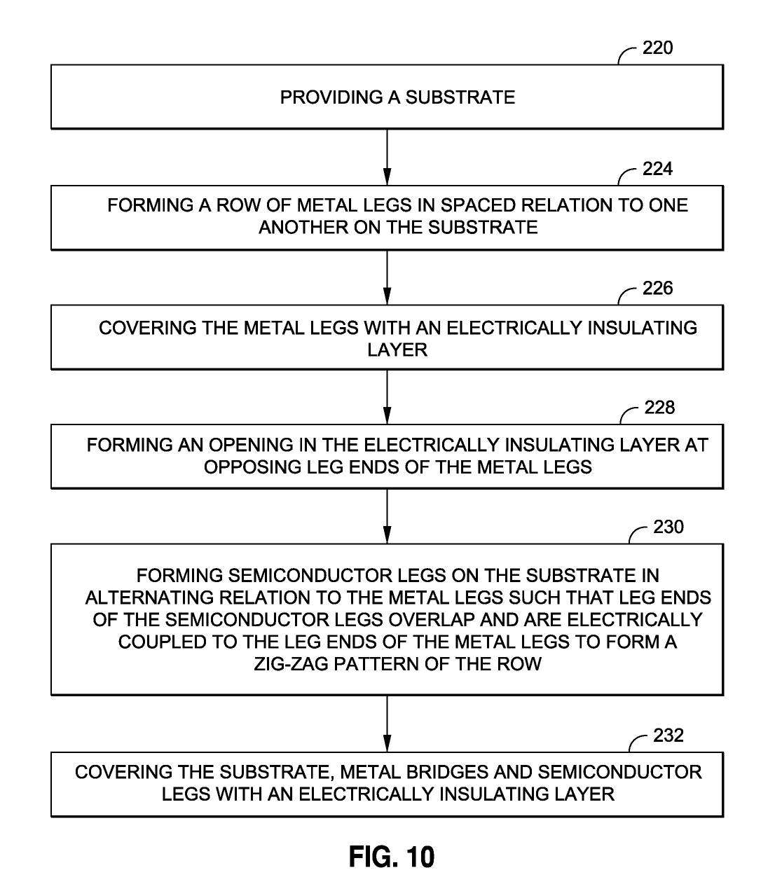

For configurations of the thermoelectric generator 10 wherein the thermoelectric legs 26 are formed of metallic material 34, such metal legs 36 may be provided in a generally reduced thickness relative to thermoelectric legs 26 formed of semiconductor material 38. For example, metal legs 36 may have a leg thickness tₗ from about 0.5 microns to about 5 microns although the metal legs 36 may be provided in any thickness. Configurations of the thermoelectric generator 10 implementing the use of metal legs 36 are illustrated in FIGS. 7A-7G and FIGS. 8A-8F as described in greater detail below.

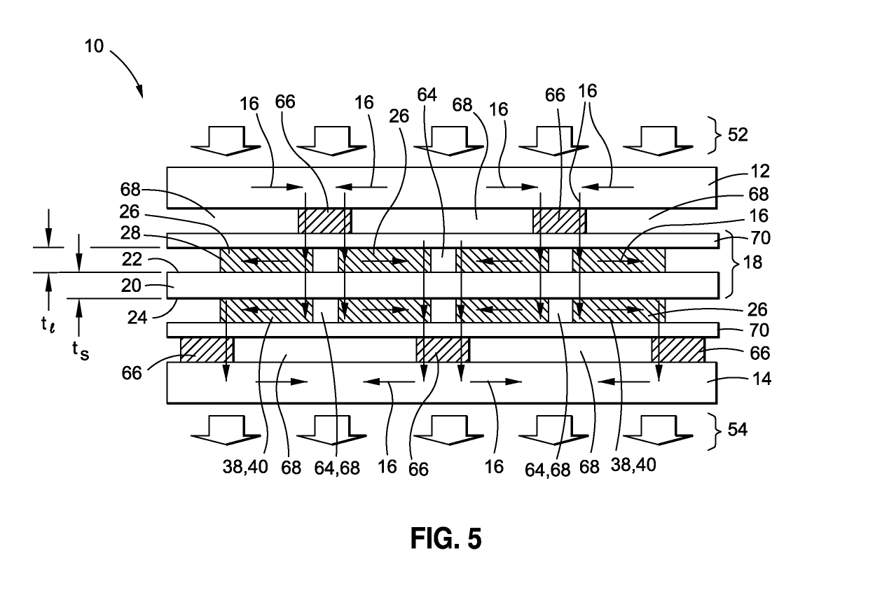

Referring still to FIGS. 3-4, shown are the thermally conductive strips 66 which may be mounted on opposite sides of the substrate 20 for thermally connecting the top and bottom plates 12, 14 to the thermoelectric legs 26. Although shown as elongate strips extending along a substantial width of the thermoelectric generator, it is also contemplated that the thermally conductive strips 66 may be configured as a plurality of segments disposed at spaced relation to one another and thermally connecting the ends of the thermoelectric legs 26 to the top plate 12 and bottom plates as illustrated in FIGS. 3 and 5. Even further, it is contemplated that the thermally conductive strips 66 may be formed as discrete or localized deposits of thermally conductive material in order to thermally connect the ends of the thermoelectric legs 26 to the top and bottom plates 12, 14. In this regard, the thermally conductive strips 66, segments or deposits may be configured in a wide variety of configurations and in a wide range of materials. For example, the thermally conductive strips 66 may be configured as strips of thermally conductive adhesive or as strips of material similar to the material from which the thermally conductive top and bottom plates 12, 14 are formed.

In this regard, the top and bottom plates 12, 14 may be formed of any suitable material including, but not limited to, metal material or ceramic material such as aluminum oxide, aluminum nitride, beryllium oxide and other suitable material having a high thermal conductivity. The thermally conductive strips 66 may be integrated into the top and/or bottom plates 12, 14. For example, a ceramic heat couple plate (i.e., top or bottom plate 12, 14) may be integrally formed with the thermally conductive strips 66 on one side of the plate. The thermally conductive strips 66 may be formed by appropriate fabrication of the top and bottom plates 12, 14 and may include dicing, laser ablation, and micro-stamping (i.e., pressing) which may be performed prior to sintering of the ceramic material. In a further embodiment, one or both of the top and bottom plates 12, 14 may be formed of ceramics with a metal pattern being formed on one side using physical vapor deposition processes (i.e., sputtering, evaporation, electron beam deposition) or electro deposition which may be followed by photolithographic structuring.

The top and bottom plates 12, 14 may optionally be formed as a stack of metal foils and which may have the thermally conductive strips 66 integrated therewithin. In this regard, metal foils may be formed into the top and bottom plates 12, 14 by pressing, folding, creasing, stamping, laser ablation or by soldering the surfaces of the top and bottom plates 12, 14 with a partially covered photolithographic mask in order to make gutter-shaped depressions for the thermally conductive strips 66. The top and bottom plates 12, 14 may be formed from silicon plates fabricated using silicon wafers wherein the thermally conductive strips 66 may be formed by micro-machining (i.e., etching) of the thermally conductive strips 66 on one side of the top and bottom plates 12, 14. The top and bottom plates 12, 14 may also be formed from metal foils wherein a pattern of thermally conductive adhesive may be formed on the metal foils by screen printing or by pin transfer. Alternatively electrically conductive top and bottom plates 12, 14 or electrically conductive layers on one or both of electrically insulated top and bottom plates 12, 14 may be used as metal contacts for the thermoelectric generator 10 if the metal contacts 76 of the foil assembly 18 are electrically connected to such electrically conductive layers.

Referring still to FIGS. 3-4, it is further contemplated that the top and bottom plates 12, 14 may be integrated into a heat exchanger or heat pipes or other specific profiles to improve heat exchange or to couple in heat from a heat source 52 or couple heat out to a heat sink 54. In this regard, one or more of the top and bottom plates 12, 14 may be integrated into a heat exchanger as a unitary structure wherein the heat exchanger is attached directly to or is integrated with the top and bottom plates 12, 14. Such an arrangement may result in reduced thermal resistance across the thermal connection between the heat exchanger and the top and bottom plates 12, 14. Furthermore, such arrangement may increase the temperature gradient across the thermoelectric generator 10 and may reduce production costs. The thermally conductive top and bottom plates 12, 14 may also be attached or bonded to the foil assembly 18 by means of the thermally conductive strips 66 using a suitable thermally conductive adhesive. Such thermally conductive adhesive may be room temperature curable or may be curable by exposure to heat and/or ultraviolet radiation.

Soldering may also be employed in order to attach the top and/or bottom plates to the thermally conductive strips 66 and/or to the foil assembly 18. For example, the top and/or bottom plates 12, 14 may include metalized strips such as in a stripe pattern to allow for soldering of the top and/or bottom plates 12, 14 to the substrate 20 and/or the electrically insulating layer 70 (e.g., photo resist layer). Furthermore, the solder can itself be used as the thermally conductive strips 66 to connect the top and/or bottom plates to the foil assembly 18. In this regard, thin metal strips preferably made of nickel may be deposited on the lower substrate surface and/or on a top surface of the electrically insulating layer 70 opposite to the thermally conductive strips 66. Such metal strips may be deposed by any suitable means including, but not limited to, sputtering and photolithographic structuring (e.g., a lift-off technique or positive resist followed by etching) in order to obtain a solderable surface and to facilitate assembly of the top and bottom plates 12, 14 and thermally conductive strips 66 by soldering.

Referring still to FIGS. 3-4, the thermoelectric legs 26 in the rows 60 are preferably electrically connected in series to the thermoelectric legs 26 of adjacent one of the rows 60. As shown in FIG. 3, the thermoelectric generator 10 may include at least one electrically insulating layer 70 such as a strip, segment or sheet of electrically insulating material which may be interposed between the thermally conductive strips 66 and the adjacent thermoelectric legs 26. For the configuration illustrated in FIG. 5, the thermoelectric generator 10 may include a pair of the electrically insulating layers with each one of the electrically insulating layers being interposed between the thermally conductive strips 66 and the thermoelectric legs 26.

Referring to FIGS. 3-5, the leg ends 28 of the thermoelectric legs 26 in each row 60 are spaced apart from the leg ends 28 of the thermoelectric legs 26 in an adjacent row 60 to define a row gap 62. As can be seen in FIGS. 3 and 5, the thermally conductive strips 66 are preferably aligned with the row 60 gaps such that a single one of the thermally conductive strips 66 facilitates flow of heat into or out of the thermoelectric leg 26 on each side of the row gap 62. Referring briefly to FIG. 5, shown is an embodiment of the thermoelectric generator 10 similar to that which is illustrated in FIG. 3 and further including thermoelectric legs 26 formed on the lower substrate surface 24 in alignment with the thermoelectric legs 26 on the upper substrate surface 22. As can be seen, the thermoelectric generator 10 includes the thermally conductive strips 66 which are mounted on opposite sides of the substrate 20 and which are aligned with opposite ends of the thermoelectric legs 26 in each one of the rows 60. Due to the formation of the thermoelectric legs 26 on both surfaces of the substrate 20, the amount of parasitic heat flow through the substrate 20 of FIG. 5 may be reduced relative to the heat flow through the thermoelectric legs 26 which may increase the efficiency of energy conversion of the thermoelectric generator 10 of FIG. 5 in comparison to the arrangement of the thermoelectric generator 10 of FIG. 3.

The thermoelectric generator 10 may also be provided in a stacked arrangement (not shown) comprising multiple foil assemblies stacked on top of one another. Each foil assembly 18 comprises at least one substrate 20 and one or more rows 60 of thermoelectric legs 26. The foil assembly 18 in a multi-foil stack may be thermally connected in parallel with one another which may improve the power output of the thermoelectric generator 10. The thermocouples 48 (i.e., pairs of thermoelectric legs 26) may be electrically connected in series in order to increase the output voltage. Alternatively, the thermocouples 48 may be electrically connected in parallel in order to increase the electrical current. For example, the thermoelectric generator 10 may include two of the foil assemblies with each foil assembly 18 including at least one substrate 20 having thermoelectric legs 26 formed on at least one of the upper and lower substrate surfaces 22, 24 thereof. The foil assemblies may be stacked back-to-back, front-to-back or front-to-front between the pair of top and bottom plates 12, 14.

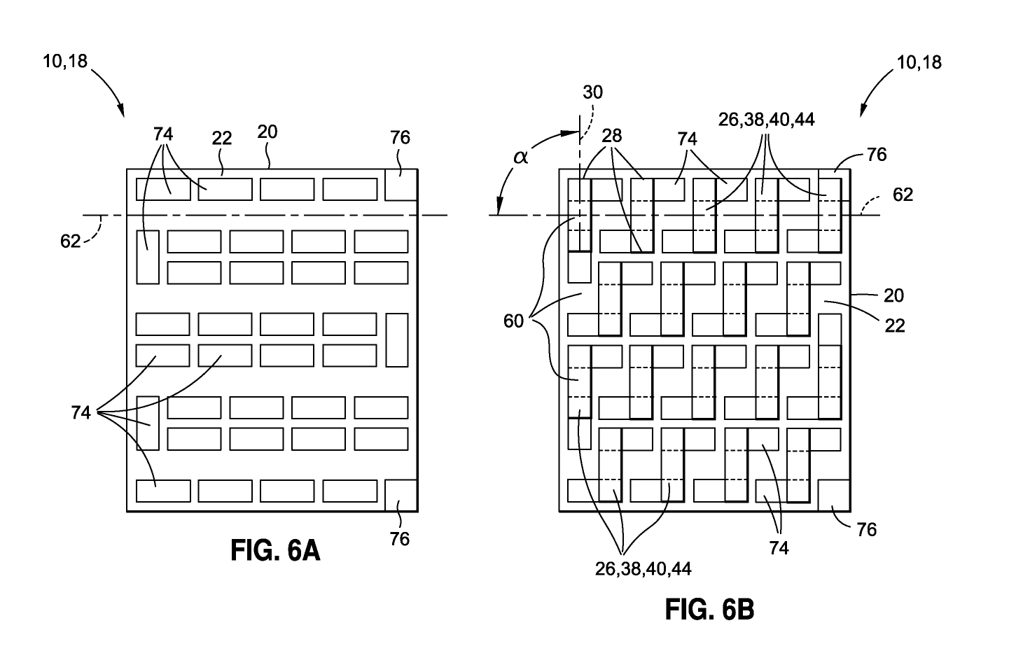

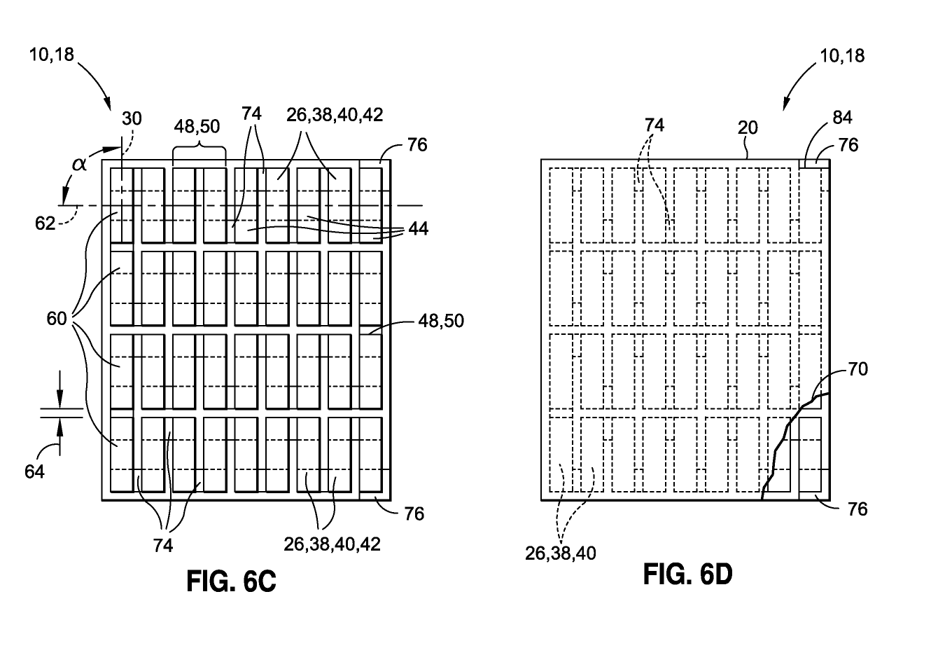

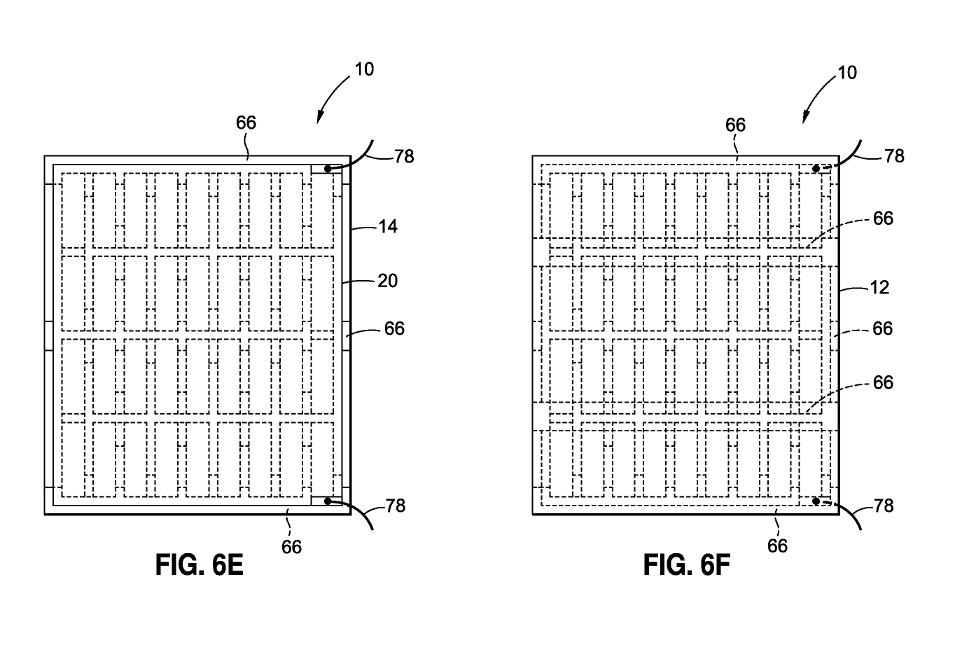

Referring to FIGS. 6A to 6F, shown is a series of schematic top views illustrating a process for fabricating an embodiment of the thermoelectric generator 10. In the illustrations of FIGS. 6A-6F, the thermoelectric generator 10 includes a plurality of metal bridges 74 for interconnecting an alternating arrangement of the thermoelectric legs 26 formed of semiconductor material 38. As can be seen in FIG. 6A, the metal bridges 74 may be generally aligned with one another in parallel arrangement on at least one of the upper and lower substrate surfaces 22, 24. The metal bridges 74 may be formed on the substrate 20 by any suitable means such as by photolithography (e.g., lift-off technique) and sputtering or any other suitable means. Advantageously, the metal bridges 74 provide a means for minimizing the electrical resistance in the thermocouples 48 and improving the thermal contact as compared to an arrangement wherein the semiconductor legs 40 of the thermocouples 48 are placed in directly overlapping relation to one another. In this regard, the metal contacts improve the uniformity of heat transfer from the thermally conductive strips 66 to the thermoelectric legs 26.

Furthermore, the deposition of a thin layer of metallic material (i.e., metal bridges and metal contacts) over a several times thicker p-type and n-type semiconductor leg may result in an increase in the total electrical resistance of the thermopile in comparison to an embodiment of the thermoelectric generator wherein thin layers of metallic material (e.g., metal bridges and metal contacts) are deposited onto the substrate prior to deposition of the semiconductor material for several reasons. Furthermore, when thin layers of metallic material are deposited over semiconductor material, such semiconductor material may have unclean surfaces wherein the surfaces may be polluted with reaction products from the etching processes. For example, if p-type semiconductor legs are first deposited on the substrate followed by depositing of n-type legs and structuring of the n-type legs, the n-type etching solution will contact the p-type legs unless care is taken to selectively etch only the n-type legs. Any contact of the n-type etching solution with the p-type legs may require reworking of the p-type legs. In contrast, if the metallic material is deposited onto the substrate first following by depositing the p-type legs, the need for rework may be eliminated because the metallic material is more resistant to attack from the n-type or p-type etching solution.

A further drawback associated with forming semiconductor legs on the substrate prior to forming metal bridges and contacts is that when relatively thin layers of metallic material (e.g., metal bridges and contacts) are deposited over the semiconductor legs, the thickness of the metallic material may become thinned out due to the relatively steep slopes of the sides of the thick semiconductor legs. In this regard, the metallic material on the sides of the semiconductor legs may have a reduced thickness in comparison to planar areas of the metallic material on top of the semiconductor legs or on top of the substrate. The thin metallic material on the sides of the semiconductor legs may result in an increase in the total electrical resistance of the thermopile.

Another drawback associated with forming semiconductor legs on the substrate prior to forming the metal bridges and contacts is that the etching of the semiconductor legs reduces the smoothness of the interface between the semiconductor legs and the metal bridges which further increases the electrical resistance of the thermopile. In addition, the thickness of the thin layer of metallic material along the upper edges of the semiconductor legs is further reduced without additional techniques to prevent such occurrence.

A further increase in the total electrical resistance of the thermopile may also occur because of a reduced thickness of metallization at the transition from the thermoelectric legs to the substrate. The reduced thickness occurs as a result of the lift-off mask which is placed over the substrate and thermoelectric legs and wherein the mask includes openings which define the shape and size of the metal bridges. The reduced thickness of metallization is a result of a shadowing effect due to the small aspect ratio of the lateral dimensions of the opening of the lift-off mask relative to the large thickness of the thermoelectric legs and, more specifically, the area of the opening that lies above the gap between the thermoelectric legs. In addition, the electrical path along the metal bridge connecting two adjacent semiconductor legs is longer due to the thickness of the semiconductor legs. Electrical resistance of the thermopile may also increase due to the relatively rough and undefined structure of etched semiconductor surfaces especially at the sides of the semiconductor legs. As such, forming the thin layers of metallic material (i.e., metal bridges and contacts) on the substrate prior to forming the semiconductor legs may provide advantages in manufacturing and performance of the thermoelectric generator. It should be noted that as disclosed herein, the process of forming thermoelectric legs comprises initially depositing a homogeneous thin film of thermoelectric material (e.g., semiconductor material) onto the substrate followed by structuring the thermoelectric material wherein portions of the homogeneous film are removed by means of a photolithographic process followed by a wet etching process. In this manner, a pattern of legs may be formed.

Referring still to FIGS. 6A to 6F, in an embodiment of the thermoelectric generator, the metal contacts 76 may be formed on the substrate 20 such as on the corners of the substrate 20 or at any other suitable location. The metal contacts 76 may provide a means for electrical connection of the series of thermoelectric legs 26 to a load such as a device that may be powered by the thermoelectric generator 10. In this regard, the thermoelectric generator 10 may include a pair of conducting wires 78 which may be physically supported by the top and/or bottom plate 12, 14 such as by using electrically and/or thermally conductive adhesive or solder. Electrical connection of the metal contacts 76 to the conducting wires 78 may be facilitated with electrically conductive adhesive, solder or any suitable bonding technique.

The pair of conducting wires 78 may be electrically connected to the respective ones of the metal contacts 76. It is further contemplated that both the top and bottom plates 12, 14 may serve as electrical contacts by which the thermoelectric generator 10 may be connected to a device. For example, one end of the series of thermoelectric legs 26 may be electrically connected to the top plate 12 while an opposite end of the series of thermoelectric legs 26 may be connected to the bottom plate 14. Such electrical connection may be facilitated through the use of electrical adhesive although bonding, soldering or any other suitable electrically conductive means may be utilized. In a further embodiment, the top and/or bottom plates may be configured as metallized ceramic plates to act as heat conductors as well as serve as electrical contacts for the thermoelectric generator 10.

FIG. 6B illustrates a second step in the process of fabricating the thermoelectric generator 10 wherein a series of alternating thermoelectric legs 26 formed of semiconductor material 38 may be deposited on the substrate 20 such that the opposing ends of the thermoelectric legs 26 at least partially overlap the metal bridges 74. In this manner, the metal bridges 74 electrically interconnect the adjacent pairs of thermoelectric legs 26. For example, FIG. 6B illustrates at least one of n-type and p-type legs 42, 44 formed on the substrate 20 using a starting material composition such as a bismuth telluride-type (i.e., Bᵢ₂Te₃-type) semiconductor material 38. As can be seen, the thermoelectric legs 26 may be oriented in substantially non-parallel relation to the row axis 62. As shown in FIG. 6B, the leg axes 30 of each one of the p-type thermoelectric legs 26 may be oriented in substantially perpendicular relation to the row axis 62. Furthermore, the thermoelectric legs 26 in the row 60 may be oriented in substantially parallel relation to one another although one or more of the thermoelectric legs 26 may be oriented at a leg-row angle α relative to the row axis 62 that is different than the orientation of the remaining ones of the thermoelectric legs 26.

The thermoelectric leg 26 may be formed of any suitable semiconductor compound such as the above-mentioned Bi₂Te₃—type semiconductor compound. For example, the p-type legs 44 may be formed from a starting compound having the following formula: (Bi_{0.15}Sb_{0.85})₂Te₃ plus about 10 at. % Te excess to about 30 at. % Te excess. The p-type semiconductor compound may have a power factor (Pₚ) of up to 45 μW/(K²*cm) at about 20° Celsius. The n-type legs 42 may be formed from a starting compound having the following formula: Bi₂(Te_{0.9}Se_{0.1})₃ plus about 10 at. % (Te_{0.9}Se_{0.1}) excess to about 30 at. % (Te_{0.9}Se_{0.1}) excess. The n-type semiconductor compound may have a power factor (Pₙ) of up to about 45 μW/(K²*cm) at about 20° Celsius.

As was indicated above, the thermoelectric legs 26 formed of semiconductor compound comprise semiconductor legs 40 which are preferably relatively thick compared to the thickness of the metal bridges 74. For example, the semiconductor legs 40 may be provided in a leg thickness tₗ of from about 15 microns to about 100 microns or more. In contrast, the metal bridges 74 may be provided in a thickness of from about 0.5 micron to about 5 microns although the metal bridges 74 may be provided in any thickness. Likewise, the metal contacts 76 may be provided in any suitable thickness.

Following the formation of the p-type legs 44 (e.g., deposition of a homogenous layer, application of a photo-resist mask followed by a wet etching process) as shown in FIG. 6B, a protective layer such as a layer of photo-resist may be applied over the p-type legs 44 prior to deposition of the n-type legs 42. By applying the layer of photo resist over the p-type legs 44, an HNO₃-based (i.e., nitric acid-based) etching solution may be used for structuring the n-type legs 42 without damaging the tungsten-aluminum films (e.g., metal legs 36 and metal contacts 76) formed on the substrate 20 with oxidized aluminum surfaces. The metal bridges may be formed on the substrate by sputtering a layer of tungsten onto the substrate followed by sputtering and/or evaporation of a layer of aluminum onto the tungsten layer followed by a layer of tungsten.

Regarding the formation of the thin layers of metallic material (i.e., metal bridges and contacts) on the substrate prior to forming the semiconductor legs, a thin layer of aluminum may initially be deposited onto the substrate to act as a buffer to absorb internal stresses caused by different thermal expansion coefficients of the tungsten relative to the polyimide material of the substrate. For example, tungsten has a thermal expansion coefficient α of 4.5×10⁻⁶ K⁻¹ as compared to a polyimide substrate such as Kapton® which has a thermal expansion coefficient α of 20×10⁻⁶ K⁻¹. Aluminum has a thermal expansion coefficient α of 23.1×10⁻⁶ K⁻¹ such that forming the aluminum on the polyimide substrate prior to forming the tungsten allows the aluminum to act as a buffer between the tungsten and the polyimide substrate. In order to improve the adhesion of the aluminum to the substrate, an ultra-thin layer of tungsten, chromium, titanium or any other suitable material with favorable bonding characteristics to polyimide may be deposited prior to deposition of the aluminum layer on the substrate. It should also be noted that tungsten is one of many different materials that could be used to form the metal bridges. The selection of the material is in consideration of minimizing the electrical contact resistance between the thermoelectric legs and the metal bridges as well as in consideration of the resistance against the etching solution and consideration of the diffusion barrier.

In an example of an etching solution for use in structuring tellurium-compound semiconductor materials such as for use in structuring the n-type legs, the etching solution may comprise one or more of nitric acid, ferric nitride, citric acid and wetting agent as active ingredients. As indicated above, the etching solution may be suitable for structuring semiconductor films of tellurium-compounds such as thin films of such semiconductor materials. Such tellurium-compounds may contain bismuth and/or antimony. The etching solutions may facilitate a consistent etching process with minimal etching of the photo-resist mask. For example, the etching solution may contain 10% to 40% by volume of 65% nitric acid (i.e., HNO₃). Additionally, the etching solution may contain 5% to 30% by mass of citric acid and citrates. 0.5% to 2.0% by mass of metallic salt resistant to at least 2 levels of valency may be added. For example, an iron oxide salt (e.g., ferric(III) salt) such as Fe₃(NO₃)₃ may be used.

Referring to FIG. 6C, the process for forming the foil assembly 18 may include forming a plurality of n-type legs 42 of a semiconductor compound in alternating relation to a plurality of existing p-type legs 44. Each one of the n-type and p-type legs 42, 44 has opposing leg ends 28 and which are formed on the substrate 20 such that the leg ends 28 overlap the metal bridges 74 at a junction 50 thereof. In this regard, the metal bridges 74 electrically interconnect the p-type legs 44 to adjacent ones of the n-type legs 42 at opposite ends of the p-type legs 44. In the illustration shown in FIG. 6C, the foil assembly 18 is provided in an arrangement wherein the n-type and p-type legs 42, 44 in each row 60 are electrically connected in series. The metal bridges 74 interconnecting the semiconductor legs 40 may be formed of any suitable material or combinations of materials including, but not limited to, tungsten, chromium, gold, nickel, aluminum, silver, copper, titanium, molybdenum, tantalum or also doped silicon carbide. In addition, the metal bridges 74 may comprise several thin layers.

For example, a layer of copper may be deposited over the polyimide substrate 20 followed by a relatively thin layer of nickel to serve as a diffusion barrier between the copper and the semiconductor leg 40 disposed over the metal bridge. The diffusion barrier may comprise any one of a variety of different materials to prevent the occurrence of undesirable reactions between overlapping dissimilar materials. An intermediate layer of nickel may be desired to improve the bonding of the copper to the substrate. In another example, the metal bridges 74 may be formed of a relatively thin layer of tungsten (e.g., ultra-thin such as several nanometers thick) initially deposited on the polyimide substrate 20 due to the favorable adhesion of tungsten to polyimide film. A thin aluminum layer (e.g., 2.5 microns) may then be deposited over the tungsten layer to serve as the electrical and thermal conductor for the metal bridge. A layer of tungsten (e.g., 150 nm) may be deposited over the aluminum layer to act as a diffusion barrier for the semiconductor legs 40 that are electrically connected to the metal bridge. In addition, the tungsten layer provides an inert surface over which the semiconductor legs 40 may be structured during the wet-etching of forming the semiconductor legs 40. The exposed surface of the aluminum layer which is not covered by the tungsten may also be oxidized by exposure to a heated environment (e.g., 1 hour exposure at 250° C.) to protect the aluminum against the nitric acid-based etching solution which may be used in the wet-etching process. Aluminum may be one of the favored materials for fabricating the metal legs 36 due to the compatible thermal expansion coefficient of aluminum with semiconductor material 38 of the thermoelectric legs 26 and the relatively high electrical and thermal conductivity. To condition the surfaces prior to deposition, dry etching as an inverse sputter operation may be applied to the surfaces such as to the substrate prior to metallization (e.g., of the metal legs and metal bridges) and/or prior to deposition of the thermoelectric legs.

Referring to FIG. 6D, shown is a top view of the foil assembly 18 wherein the electrically insulating layer 70 is disposed over the thermoelectric legs 26 and metal bridges 74 as a protective barrier to electrically insulate the thermoelectric legs 26. Notches 84 may be included in the protective layer in order to provide an opening 72 for the metal contacts 76 to facilitate electrical connecting to a conducting wire 78. The metal contacts 76 may be formed of any suitable material such as those described above with regard to forming the metal bridges. The metal contacts 76 may optionally include a thin layer of nickel which may be deposited by any suitable means including evaporation, sputtering, and/or galvanic electro-deposition. The nickel layer may improve the adhesion and act as a diffusion barrier for a layer of gold which may be formed over the nickel layer of the metal contact. The metal contacts 76 may optionally be formed of gold without the nickel layer.

Referring to FIG. 6E, shown is a top schematic view of the foil assembly 18 wherein the bottom plate 14 is attached to the lower substrate surface 24 by means of the thermally conductive strips 66 best seen in FIG. 3. As was earlier indicated, the thermally conductive strips 66 may be integrally formed with the bottom plate 14 or the thermally conductive strips 66 may be provided as separate components. FIG. 6F illustrates the mounting of the top plate 12 to the foil assembly 18 by means of the thermally conductive strips 66. The thermally conductive strips 66 may be positioned similar to the positioning illustrated in FIG. 3.

Referring briefly to FIG. 1, the thermoelectric generator 10 illustrated in FIGS. 6A-6F may include a sealant 80 applied to the perimeter edges to protect the interior of the thermoelectric generator 10 against the environment and to provide a barrier to moisture, dirt, chemicals and other contaminants. Furthermore, by filling the perimeter edges between the top and bottom plates 12, 14, the sealant 80 may enhance the mechanical stability of the thermoelectric generator 10. The sealant 80 preferably has a relatively low thermal conductivity. In a further embodiment, sealant 80 may be installed in the thermal gaps 68 for improved mechanical stability of the thermoelectric generator 10. However, the thermal gaps 68 may be filled with any material having a low thermal conductivity including, but not limited to, gaseous material such as air, nitrogen, argon, krypton, xenon or any other suitable gas, liquid or solid material or combination thereof.

Referring now to FIGS. 7A-7F, shown is a further embodiment of the thermoelectric generator 10 comprising alternating metal legs 36 and semiconductor legs 40. As can be seen, the leg ends 28 of the thermoelectric legs 26 overlap one another at a junction 50 thereof such that the thermoelectric legs 26 form a zig-zag pattern. In this regard, the zig-zag pattern increases the density of the thermoelectric legs 26 on the substrate 20. The thermoelectric legs 26 comprise semiconductor legs 40 (i.e., either n-type or p-type legs 44) in alternating arrangement with metal legs 36 which results in a lower power output relative to the power output for an arrangement of alternating n-type and p-type legs 44. Although the power output of the configuration illustrated in FIGS. 7A-7F is lower, the increased density of the legs partially compensates for the relatively lower power output. Furthermore, because only one type of semiconductor material 38 is required (e.g., either n-type or p-type), the production costs for the alternating metal legs 36 and semiconductor legs 40 is reduced.

In addition, the zig-zag pattern illustrated in FIGS. 7A-7F represents a variation of the meandering pattern and therefore provides the advantages associated with the reduction in internal stresses in the thermoelectric legs 26. In the embodiment of the thermoelectric generator 10 illustrated in FIG. 7A-7F, the metal leg 36 has a relatively small thickness compared to the relatively larger thickness of the semiconductor leg 40 which is adjacent to the metal leg 36.

In FIG. 7A, metal legs 36 may be deposited onto the substrate 20 at an angle which is represented in FIG. 7A as a leg-row angle α. The metal legs 36 may be formed on the substrate 20 by any suitable manner including, but not limited to, photolithography (e.g., lift-off technique) and sputtering. As can be seen, the metal legs 36 may be oriented in non-parallel relation to the row axis 62 and may be generally oriented in parallel relation to one another although certain ones of the metal legs 36 may be oriented at a different leg-row angle α in order to facilitate interconnection with an adjacent one of the rows 60.

Referring to FIG. 7B, shown is an electrically insulating layer 70 which may be applied over the metal legs 36 in order to electrically insulate the metal legs 36 from a series of semiconductor legs 40 (i.e., n-type or p-type legs 42, 44). As can be seen in FIG. 7C, the semiconductor legs 40 are electrically insulated from the metal legs 36 along a substantial length of the semiconductor legs 40 by forming the electrically insulating layer 70 over the metal legs 36. However, the metal legs 36 may be interconnected to the semiconductor legs 40 via openings 72 formed in the electrically insulating layer 70 as illustrated in FIG. 7B. In this regard, the leg ends 28 of the semiconductor legs 40 overlap the legs ends of the metal legs 36 at junction 50. In addition, the leg ends 28 may be electrically connected to the ends of the metal legs 36. The semiconductor legs 40 may comprise n-type legs 42 or p-type legs 44. As indicated above with regard to the metal bridges 74, the metal legs 36 may be provided in any suitable material including, but not limited to, tungsten, chromium, gold, titanium, tantalum, molybdenum, and doped silicon carbide as well as less expensive materials including, but not limited to, nickel, aluminum and copper and combinations thereof. The leg ends 28 of the semiconductor legs 40 may be bonded to the leg ends 28 of the metal legs 36 through the openings 72 of the electrically insulating layer 70 by using any suitable electrically conductive adhesive or any other suitable means.

Referring to FIG. 7D, shown is a second electrically insulating layer 70 which may be applied as a protective coating over the combination of metal legs 36 and semiconductor legs 40. In FIG. 7E the bottom plate 14 may be thermally connected to the substrate 20 by means of the thermally conductive strips 66 in a manner similar to that which was described above with regard to FIG. 6F. FIG. 7F illustrates the thermal connection of the top plate 12 to the thermoelectric legs 26 by means of the thermally conductive strips 66. Referring to FIG. 7G, shown is a partial cross-sectional view taken along lines 7G-7G of FIG. 7F and illustrating the relative positioning of the thermally conductive strips 66 at opposite ends of the thermoelectric legs 26. As can also be seen in FIG. 7G, the electrically insulating layer 70 is shown applied over the metal legs 36 with openings 72 formed on the ends of the metal legs 36 for electrically coupling to the leg ends 28 of the semiconductor legs 40. A second electrically insulating layer 70 can be seen as being applied over the semiconductor legs 40 for electrically insulating the foil assembly 18 with the top plate. FIG. 7G further illustrates the direction of heat flow from the heat source 52 top plate 12 to the heat sink 54 bottom plate 14.

Referring briefly to FIG. 7C, shown are the metal legs 36 and semiconductor legs 40 forming a leg-leg angle θ which may preferably, but optionally, form an acute angle relative to one another in order to increase the density of thermocouples 48 on the substrate 20. Although the leg-leg angle θ may be consistent throughout the zig-zag pattern, the leg-leg angle θ may vary between the thermocouples 48. In the arrangement shown in FIGS. 7A-7F, the thermoelectric legs 26 form a zig-zag pattern which eliminates the need for a separate element connecting the ends of the adjacently disposed thermoelectric legs 26 such as the metal bridge 74 element required in the thermoelectric generator 10 illustrated in FIGS. 6A-6F.

Referring to FIGS. 8A-8F, shown is a further embodiment of the thermoelectric generator 10 including alternating semiconductor and metal legs 40, 36 and being formed in a zig-zag pattern similar to that which is described with regard to the embodiment illustrated in FIGS. 7A-7F. In this regard, the zig-zag pattern illustrated in FIGS. 8C-8F results in a doubling of the density of the thermocouples 48 on the substrate 20 relative to the meandering arrangement illustrated in FIGS. 6C-6F. As indicated above with regard to FIGS. 7A-7F, although the power output of such a configuration is lower relative to the power output for an arrangement of alternating n-type and p-type legs 44, the doubling of the leg density partially compensates for the lower relative power output. Furthermore, production costs are reduced because only one type of semiconductor material 38 is required (e.g., either n-type or p-type).

In the embodiment of FIG. 8A-8F, the semiconductor legs 40 are oriented generally perpendicularly relative to the row axis 62 as a means to further increase the density of thermoelectric legs 26 on the substrate 20. FIG. 8A illustrates the disposition or formation of metal legs 36 in rows 60 on the substrate 20 wherein the metal legs 36 are oriented at a leg-row angle α which is non-perpendicular relative to the row axis 62. FIG. 8B illustrates the application of the electrically insulating layers and the formation of the plurality of openings 72 at the leg ends 28. FIG. 8C illustrates the deposition of semiconductor legs 40 which are oriented at a leg-row angle α wherein the semiconductor legs 40 are generally perpendicular relative to the row axis 62. Due to the openings 72 formed in the electrically insulating layer 70, the leg ends 28 of the semiconductor legs 40 overlap with the leg ends 28 of the metal legs 36 and are electrically coupled thereto. As indicated above with regard to the embodiment illustrated in FIGS. 7A-7F, although the leg-leg angle θ may be consistent throughout the zig-zag pattern, the leg-leg angle θ may vary between the thermocouples 48. FIG. 8D illustrates the application of a second electrically insulating layer 70 to electrically insulate the foil assembly 18 from the top plate. FIG. 8E illustrates the connection of the bottom plate 14 to the foil assembly 18 by means of the thermally conductive strips 66 similar to that described above. Likewise, FIG. 8F illustrates the connection of the top plate 12 to the foil assembly 18 by means of the thermally conductive strips 66.

In each of the configurations illustrated in FIGS. 6A-6F, 7A-7F and 8A-8F, the assembled thermoelectric generator 10 may be protected from the environment by means of the sealant 80 which may be applied around a perimeter edge of the thermoelectric generator 10 as illustrated in FIG. 1. The sealant 80 having a low thermal conductivity may also be inserted into the thermal gaps 68 in order to provide protection against the elements and/or to enhance the mechanical stability of the thermoelectric generator 10. As indicated above, the thermal gaps may also be filled with any suitable material in any form and preferably having a low thermal conductivity. For example, the thermal gaps may be filled with air, nitrogen, argon, krypton, xenon or any other suitable gas, liquid or solid material or combination thereof.

A number of different fabrication techniques may be used to form the thermoelectric generator including, but not limited to, wafer technology and/or roll-to-roll processing or combinations thereof to form the foil assembly 18. For example, in wafer technology with regard to the embodiment illustrated in FIGS. 6A-6F, the process may initially comprise providing the substrate 20 which may be formed of any material including, but not limited to, polyimide material such as Kapton®. The substrate may be mounted on a frame for support in order to form a wafer. Once the substrate is supported, the metal bridges 74 and metal contacts 76 may be deposited by photolithography and sputtering.

In this regard, the metal bridges 74 between the thermoelectric legs 26 and/or metal contacts 76 located opposite ends of the thermopiles may be generated prior to the etching processes and therefore may require protection against applied etching solutions such as solutions based on fluoboric acid, perchloric acid, or nitric acid used in etching the semiconductor legs. As indicated above, such metal contacts 76 and metal bridges 74 and other metal films may include tungsten, chromium, and/or gold, platinum, titanium, tantalum, molybdenum and doped silicon carbide and may be applied by sputtering or thermal evaporation. The metal contacts 76 and metal bridges 74 may be structured using photolithography such as lift-off photolithography or any other suitable technique. The metal contacts 76 and metal bridges 74 may be formed from one or more preferred low-cost metals having high and thermal electrical conductivities. As indicated above, such metals include, but are not limited to, aluminum (Al), nickel (Ni), silver (Ag) or copper (Cu) or any combination thereof. As indicated above, such metal material may be applied by sputtering or thermal evaporation and may be structured by using photolithography.

In case that the preferred low-cost metals such as aluminum, nickel, silver or copper are deposited prior to the etching processes, a protective layer may be applied using a thin layer of metallic material 34 such as tungsten, chromium, gold, titanium, molybdenum, tantalum or doped silicon carbide. The protective layer may be applied by photolithography using a relatively large lift-off mask applied to the top of the metallic material 34 followed by sputtering or thermal evaporation through the lift-off mask. Alternatively, the protective layer may be applied after sputtering operations by dry and/or wet etching after the application of the photolithographic mask. Aluminum may be oxidized to provide resistance to a HNO₃-based etching solution. Optionally, the process of forming the metal contacts 76 may include electro-deposition of gold, nickel or silver or a combination of such materials for electrically coupling the foil assembly 18 to a load or device to be powered by the thermoelectric generator.

As was also mentioned above, relatively thin metal strips formed of any suitable material and preferably formed of nickel may be deposited on the lower substrate surface and/or on top of the electrically insulating layer 70 opposite the thermoelectric legs 26. The metal material may be deposited by sputtering and photolithographic structuring such as by using a lift-off technique or positive resist followed by etching. As was earlier indicated, such metal material may provide a location for applying a solderable surface for assembling the top and bottom plates 12, 14 to the foil assembly 18 using thermally conductive strips 66 by soldering.

Following the formation of the metal material (e.g., metal bridges 74, metal contacts 76) on the substrate, the p-type legs 44 may be formed on the substrate 20 such that the leg ends overlap the ends of the metal bridges 74. The p-type legs 44 may be formed of semiconductor material 38 by sputtering, photolithography and wet chemical etching using a suitable etchant such as an etching solution based on fluoboric acid or nitric acid in order to generate the p-type legs 44 of the thermocouples. The metal contacts, metal legs which may be exposed to the etching solution may be protected by a photo resist coating. Likewise, n-type legs 42 may be formed of a suitable semiconductor material 38 such as a Bi₂Te₃—type semiconductor compound such as by sputtering, photolithography and wet chemical etching using a suitable selective etchant such as an etching solution based on nitric acid or a selective etching solution based on perchloric acid in order to generate the n-type legs 42 of the thermocouples. The n-type and p-type legs 44 may be deposited onto the substrate 20 using a series of alternating hot and cold sputtering steps. The cold sputtering step may be performed at a temperature of in the range of from about 10° Celsius to about 100° Celsius. The hot sputtering step being performed at a temperature in the range of from about 200° Celsius to about 350° Celsius.

A protective photo resist may be applied over the p-type legs 44 prior to deposition of the n-type legs 42 to allow for the use of the HNO₃-based etching solution for structuring the n-type legs 42. The nitric-acid based solution etches the n-type and p-type legs at different rates. The nitric-acid based solution may be performed at a temperature which reduces the rate of etching of the p-type legs such that the need to apply a photo-resist layer may be reduced or eliminated. In addition, changing the composition or ratios of components of the etching solution may allow for selective etching of the n-type material. By using the HNO₃-based etching solution for structuring both n-type and p-type legs 44, the tungsten-aluminum metal legs 36 and metal contacts 76 formed on the substrate 20 with oxidized aluminum surfaces are resistant to the HNO₃-based etching solution.

Following the fabrication of the foil assembly 18, the electrically insulating layer 70 may be applied over the thermoelectric legs 26 as illustrated in FIGS. 6D, 7D and 8D using any suitable process such as photolithography. The electrically insulating layer 70 may be annealed prior to cutting or dicing the foil assembly 18 to the final shape and size. The top and bottom plates 12, 14 may be mounted to the foil assembly 18 such that the foil assembly 18 is sandwiched therebetween. As indicated above, the mounting of the top and bottom plates 12, 14 may comprise a variety of different means by which the thermally conductive strips 66 are used to thermally connect the top and bottom plates 12, 14 to the foil assembly 18.

A further embodiment of a method of forming the thermoelectric generator 10 may comprise forming the n-type and p-type legs 44 on the substrate 20 followed by deposition of metal bridge 74 to electrically connect the leg ends of the adjacent pairs of thermoelectric legs 26 similar to a process disclosed in U.S. Pat. No. 6,958,443 filed on May 19, 2003 and entitled LOW POWER THERMOELECTRIC GENERATOR, the entire contents of which is expressly incorporated by reference herein. For example, the process may comprise forming the p-type legs 44 (or n-type legs 42) on the substrate 20 by sputtering, photolithography and wet chemical etching of p-type semiconductor material 38 to generate the p-type legs 44 of the thermocouples. The n-type legs 42 (or p-type legs 44) may then be formed on the substrate 20 by sputtering, photolithography and selective wet chemical etching of n-type semiconductor material 38 to generate the n-type legs 42 of the thermocouples. Metallic material 34 comprising the metal bridges 74 and metal contacts 76 may be applied using metallization by photolithography and sputtering. A protective cover layer such as the above-described electrically insulating layer 70 may be applied using photolithography followed by an annealing step. Once finalized, the foil assembly 18 may be cutting or diced into the desired shape and size prior to mounting the top and bottom plates 12, 14.

In an alternative embodiment, the method of forming the thermoelectric generator 10 may include a process similar to that which is described above with reference to FIGS. 6A-6F wherein metal bridges 74 and/or metal contacts 76 are formed on the substrate 20 followed by forming the p-type and n-type legs 42 such the leg ends of the p-type and n-type legs 42 overlap the ends of the metal bridges 74. A second set of metal bridges 74 and metal contacts 76 may be deposited over the originally deposited metal bridges 74 and metal contacts 76 in general alignment therewith such that the leg ends of the n-type and p-type legs 44 are sandwiched between the metal bridges 74. Such an arrangement may reinforce the earlier-formed metal bridges 74 and metal contacts 76. The dicing or cutting steps may be repeated to shape and or size the foil assembly 18 prior to mounting the top and bottom plates 12, 14 to the foil assembly 18.

With regard to the embodiments of the thermoelectric generator 10 having alternating thermoelectric legs 26 of semiconductor material 38 and metallic material 34 as illustrated in FIGS. 7A-7F and 8A-8F and described above, the process may include providing the substrate 20 followed by forming the metal legs 36 and metal contacts 76 on the substrate. The metal legs 36 and metal contacts 76 may be deposited using any suitable manner as described above such as photolithography and sputtering to generate the metal contacts 76 and the metal legs 36 of the thermocouples. The electrically insulating layer 70 may then be applied over the substrate 20 and covering the metal legs 36 except the legs ends 38 by using photolithography after which the electrically insulating layer 70 may be annealed. The p-type legs 44 may be deposited by sputtering, photolithography and wet chemical etching of p-type semiconductor to generate the p-type legs 44 of the thermocouples. A cover layer of electrically insulating layer 70 may be applied using photolithography after which the electrically insulating layer 70 may be annealed. The foil assembly 18 may be cut into a desired shape followed by mounting of the top and bottom plates 12, 14 in a manner similar to that which is described above.

Although a number of different fabrication techniques may be utilized in forming the thermoelectric legs 26 and/or metal legs 36 onto the substrate, the method of sputtering, such as magnetron or plasmatron sputtering, may preferably be utilized with the aid of high vacuum deposition equipment. Sputtering may be utilized for deposition of relatively thick semiconductor material 38 such as bismuth telluride-type semiconductor material 38 onto the relatively thin substrate. When used in conjunction with the material systems described above, significantly high power output is achievable with the thermoelectric generator 10 of the present disclosure. Such increased power output is due in part to the use of bismuth telluride-type (Bi₂Te₃-type) material systems which have a relatively high figure of merit (Z) compared to other material systems in the room temperature range and which effectively operate in a range of from about 32° F. to about 212° F. (i.e., equivalent to a range of about 0° C. to about 100° C.).

The efficiency of thermoelectric generator 10 may be characterized by a thermoelectric figure of merit (Z), defined by the formula: Z═S²σ/κ, where σ and κ are the electrical conductivity and thermal conductivity, respectively, and where S is the Seebeck coefficient expressed in microvolts per degree K (μV/K). Z can be rewritten as P/κ where P is the power factor.

Due to the unique material compositions of the thermoelectric legs 26 of the present invention in combination with the deposition procedure, relatively high values for the power factor (P) of the semiconductor material 38 are achievable. For example, forming the Bi₂Te₃-type semiconductor material 38 onto the substrate 20 by sputtering may result in improved values for the power factor for both the p-type and n-type legs 42 as compared to prior art arrangements.

More specifically, the use of an optimized sputtering procedure for the p-type legs 44 with Bi₂Te₃-type semiconductor material 38 as the starting material, the Seebeck coefficient (Sₚ) may be approximately 210 μV/K with an electrical conductivity (σₚ) of approximately 800 1/(Ω*cm) for a power factor (Pₚ) of approximately 35 μW/(K²*cm) in the room temperature range. For the n-type legs 42 with Bi₂Te₃-type semiconductor material 38 as the starting material, the Seebeck coefficient (Sₙ) may be approximately −180 μV/K while the electrical conductivity (σₙ) may be approximately 700 1/(Ω*cm) for a power factor (Pₙ) of approximately 23 μW/(K²*cm) in the room temperature range.

The foil assemblies as described above may also be fabricated using roll-to-roll processing techniques in order to deposit the series of the thermoelectric legs 26 onto at least one of the upper and lower substrate surfaces 22, 24. Such roll-to-roll processing may be similar to that which is disclosed in U.S. Pat. No. 6,933,098 issued on Aug. 23, 2005 to Chan-Park, et al. and entitled PROCESS FOR ROLL-TO-ROLL MANUFACTURE OF A DISPLAY BY SYNCHRONIZED PHOTOLITHOGRAPHIC EXPOSURE ON A SUBSTRATE WEB, the entire contents of which is expressly incorporated herein by reference. Metal bridges 74 and metal contacts 76 may likewise be deposited onto at least one of the upper and lower substrate surfaces 22, 24 using a similar roll-to-roll processing. Likewise, the embodiments of the thermoelectric generator 10 disclosed herein may be fabricated by one or more of the methodologies disclosed in U.S. Patent Publication No. 20090025771 filed on Sep. 30, 2008 and entitled LOW POWER THERMOELECTRIC GENERATOR, the entire contents of which is expressly incorporated by reference herein.

The thermoelectric generator 10 as disclosed in the various embodiments may exhibit a variety of performance parameters depending upon the material systems, the geometries of the components and the arrangements of the thermoelectric legs 26, metal bridges 74, substrate 20, thermally conductive strips 66, and the top and bottom plates 12, 14. For example, for a temperature gradient of approximately 5 K between the top and bottom plates, 12, 14, the thermoelectric generator 10 may provide an open thermoelectric voltage output of between approximately 0.2 V and approximately 2.0 V as may be measured across the opposite ends of the series of rows of thermoelectric legs 26 such as at the opposing conductive wires illustrated in FIG. 1. The temperature gradient between the top and bottom plates 12, 14 is defined as the temperature differential across the thermoelectric generator and from the top plate to the bottom plate or from the bottom plate to the plate. For a temperature gradient of approximately 5 K between the top and bottom plates, 12, 14, the thermoelectric generator 10 may provide a thermoelectric voltage output at matched load of between approximately 0.1 V and approximately 1.0 V. The electrical current of the thermoelectric generator 10 may be within the range of approximately 0.1 mA to approximately 5.0 mA for a temperature gradient of approximately 5 K between the top and bottom plates, 12, 14, although the thermoelectric generator 10 may be configured to provide a current output above or below the 0.1 mA and 5.0 mA range. The thermoelectric generator 10 may provide a power output of between approximately 0.1 mW and approximately 0.5 mW for a temperature gradient of approximately 5 K between the top and bottom plates, 12, 14. Efficiency of energy conversion of the thermoelectric generator 10 may be between approximately 0.02% and approximately 0.20% for a temperature gradient of approximately 5 K between the top and bottom plates, 12, 14. The power output density defined as the power output for substrate area may be within the range of between approximately 0.1 mW/cm² and approximately 0.5 mW/cm² for a temperature gradient of approximately 5 K between the top and bottom plates, 12, 14. The thermoelectric generator 10 may exhibit a thermal resistance of between approximately 10 K/W and approximately 20 K/W. However, as indicated above, the performance parameters of the thermoelectric generator 10 are dependent upon the material systems and geometries of the components that make up the thermoelectric generator 10 and therefore may fall outside of the above-stated performance ranges.

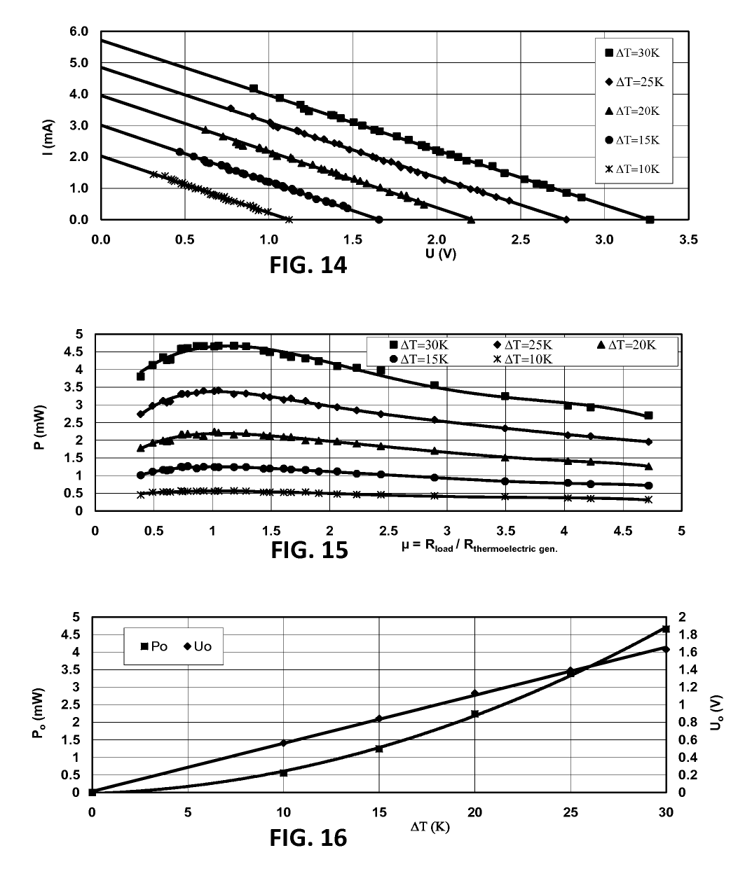

Referring to FIGS. 11-16, shown are plots illustrating the power characteristics and electric parameters of the thermoelectric generator 10 which may vary according to the temperature differential between the top plate 12 and the bottom plate 14. For example, FIGS. 11 and 14 are plots of electrical parameters of the thermoelectric generator 10 for various temperature differentials between the top and bottom plates 12, 14. More specifically, FIGS. 11 and 14 are plots of voltage in volts versus electrical current measured in micro-amps. As can be seen in FIG. 11, the thermoelectric generator 10 provides an open circuit voltage of approximately 0.55 volts and a short circuit electrical current output of approximately 1000 micro-amps (μA) at a temperature gradient of 5 K.

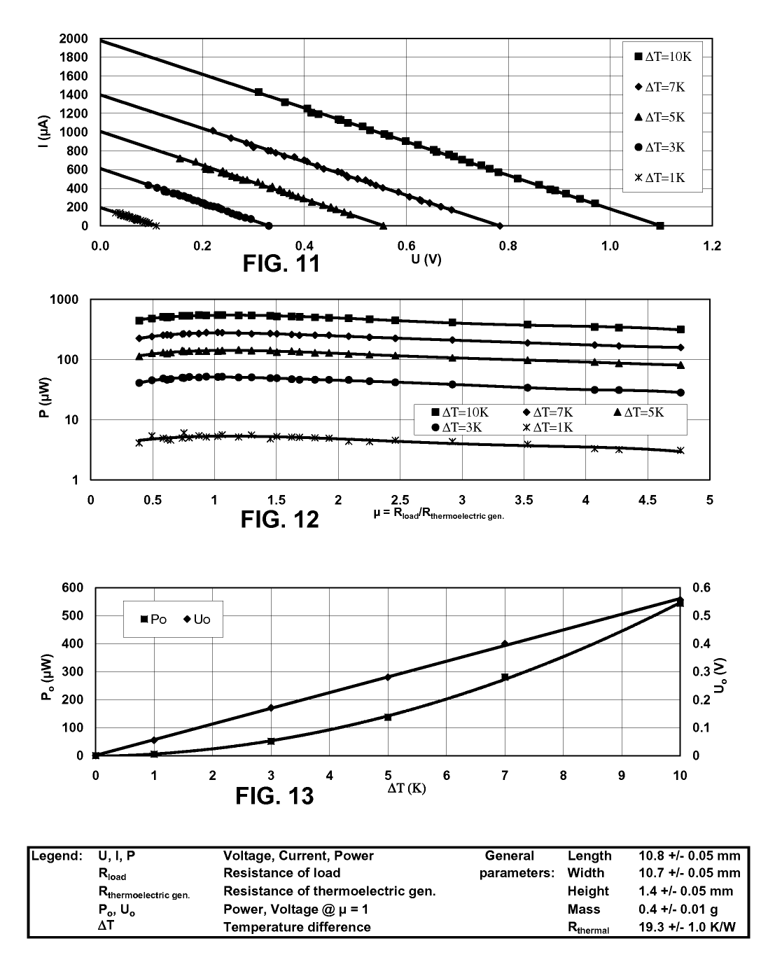

FIGS. 12 and 15 are plots of power output in the case of a matched load indicated on the plot as a ratio of resistance of a load over resistance of the thermoelectric generator 10. As can be seen in FIG. 12, for the case where the ratio of the resistance of the load to the resistance of the thermoelectric generator 10 is approximately 1, the electrical power output is approximately 140 microwatts (μW) at a temperature differential of 5 K across the top and bottom plates 12, 14.

Referring to FIGS. 13 and 16, shown are plots of power output of the thermoelectric generator 10 at matched load (i.e., ratio of resistance of load to resistance of the thermoelectric generator equals 1) to temperature difference across the top and bottom plates 12, 14. As can be seen in FIG. 13, the thermoelectric generator 10 provides a voltage output of approximately 0.28 volts at a temperature gradient of 5 K and a power output of approximately 140 μW at such matched load. Such measurements as referenced in FIGS. 11-16 are taken at basic temperatures of 30° C. Furthermore, as can be seen by reference to FIG. 13, both the power output and the voltage output of the thermoelectric generator 10 generally increase with the corresponding increase in the temperature gradient across the top and bottom plates 12, 14.

Additional modifications and improvements of the present disclosure may be apparent to those of ordinary skill in the art. Thus, the particular combination of parts described and illustrated herein is intended to represent only certain embodiments of the present disclosure and is not intended to serve as limitations of alternative embodiments or devices within the spirit and scope of the disclosure.

What is claimed is:

1. A thermoelectric generator, comprising:
a pair of top and bottom plates;
a substrate interposed between the top and bottom plates, the substrate having upper and lower substrate surfaces and being formed of an electrically insulating material having a relatively low thermal conductivity;
a series of thermoelectric legs formed of alternating dissimilar materials arranged in at least one row on at least one of the upper and lower substrate surfaces, each one of the thermoelectric legs defining a leg axis oriented in non-parallel relation to the row axis; and
at least one pair of thermally conductive strips mounted on opposite sides of the substrate and being aligned with opposite ends of the thermoelectric legs in the row such that one end of the thermoelectric legs is in thermal contact with the top plate and the opposite end of the thermoelectric legs is in thermal contact with the bottom plate, the thermally conductive strips defining thermal gaps between the thermoelectric legs and the top and bottom plates causing heat to flow lengthwise through the thermoelectric legs.

2. The thermoelectric generator of claim 1 wherein:
electrical current flows through the legs along a direction parallel to the plane of the substrate and parallel to the leg axis of each one of the thermoelectric legs.

3. The thermoelectric generator of claim 1 wherein:
each one of the upper and lower substrate surfaces includes at least one row of the thermoelectric legs.

4. The thermoelectric generator of claim 1 further including:
at least one electrically insulating layer interposed between the thermally conductive strips and the thermoelectric legs.

5. The thermoelectric generator of claim 1 further comprising:
a plurality of the rows formed on the substrate;
the thermoelectric legs of the rows being electrically connected in series.

6. The thermoelectric generator of claim 1 wherein:
the substrate includes a plurality of the rows;
the ends of the thermoelectric legs in one of the rows being spaced from the ends of the thermoelectric legs in an adjacent one of the rows to define a row gap;
the thermally conductive strip being aligned with the row gap.

7. The thermoelectric generator of claim 1 wherein:
the leg axes of the thermoelectric legs are oriented in substantially perpendicular relation to the row axis.

8. The thermoelectric generator of claim 1 wherein:
the thermoelectric legs in the row are oriented in substantially parallel relation to one another.

9. The thermoelectric generator of claim 1 wherein:
the dissimilar materials comprise dissimilar semiconductor material such that the thermoelectric legs comprise n-type and p-type legs;
at least one of the n-type and p-type legs being formed from a starting material comprising Bi₂Te₃-type semiconductor material.

10. The thermoelectric generator of claim 1 further comprising:
a plurality of metal bridges formed on the substrate;
the dissimilar materials comprise dissimilar semiconductor material such that the thermoelectric legs comprise n-type and p-type legs;
each one of the n-type and p-type legs having opposing leg ends, the legs ends overlapping the metal bridges such that the metal bridges electrically interconnect the p-type legs to adjacent ones of the n-type legs at opposite ends of the p-type legs.

11. The thermoelectric generator of claim 10, wherein:
the metal bridges are formed of metallic material comprising at least one of the following: tungsten, chromium, gold, nickel, aluminum, silver, copper, titanium, molybdenum, tantalum, doped silicon carbide.

12. The thermoelectric generator of claim 1, wherein:
the dissimilar materials comprise metallic material and semiconductor material such that the thermoelectric legs comprise metal legs and one of n-type and p-type legs;
the metallic material of the metal legs comprising at least one of the following: tungsten, chromium, gold, nickel, aluminum, silver, copper, titanium, molybdenum, tantalum, doped silicon carbide.

13. The thermoelectric generator of claim 12, wherein:
the semiconductor material of the n-type and p-type legs comprises Bi₂Te₃-type semiconductor material.

14. The thermoelectric generator of claim 12, wherein:
the metal legs are formed on the substrate;
the semiconductor legs being electrically insulated from the metal legs along a substantial length of the semiconductor legs;
the leg ends of the semiconductor legs overlapping and being electrically coupled to the leg ends of the metal legs.

15. The thermoelectric generator of claim 14 further including:
an electrically insulating layer interposed between the metal legs and the semiconductor legs and having an opening at each one of the legs ends for electrically coupling the leg ends.

16. The thermoelectric generator of claim 12, wherein:
the leg axes of adjacent pairs of the thermoelectric legs form an acute angle such that the series of thermoelectric legs in the row form a zig-zag pattern.

17. The thermoelectric generator of claim 1 wherein:
the dissimilar materials comprise at least one of the following:
metallic material and semiconductor material such that the thermoelectric legs comprise metal legs and one of n-type and p-type legs;
semiconductor material such that the thermoelectric legs comprise n-type and p-type legs;
at least one of the n-type and p-type legs having a leg thickness in the range of from about 15 microns to about 100 microns, a width in the range of from about 10 microns to about 500 microns and a length in the range of from about 50 microns to about 500 microns;
the metal legs have a leg thickness in the range of from about 0.5 micron to about 5 microns, a width in the range of from about 10 microns to about 500 microns and a length in the range of from about 50 microns to about 500 microns.

18. The thermoelectric generator of claim 17 wherein:
each one of the n-type and p-type legs has a leg thickness of about 20 to about 35 microns.

19. The thermoelectric generator of claim 17 wherein:
the substrate has a substrate thickness;
the leg thickness of the n-type and p-type legs is about 1 to about 10 times the substrate thickness;
the substrate thickness is about 1 to about 50 times the leg thickness of the metal legs.

20. The thermoelectric generator of claim 19 wherein:
the thickness ratio of the leg thickness of the n-type and p-type to the substrate thickness legs is within the range of from about 2 to about 4;
the thickness ratio of the substrate thickness to the leg thickness of the metal legs is within the range of from about 10 to about 15.

21. The thermoelectric generator of claim 19 wherein:
the substrate is formed of polyimide material.

22. The thermoelectric generator of claim 1 having at least one of the following performance parameters at a temperature gradient of approximately 5 K between the top and bottom plates:
open thermoelectric voltage output of between approximately 0.2 V and approximately 2.0 V;
thermoelectric voltage output at matched load of between approximately 0.1 V and approximately 1.0 V;
electrical current of between approximately 0.1 mA and approximately 5.0 mA;
power output of between approximately 0.1 mW and approximately 0.5 mW;
power output density of between approximately 0.1 mW/cm² and approximately 0.5 mW/cm²;
efficiency of energy conversion of between approximately 0.02% and approximately 0.2%.

23. The thermoelectric generator of claim 1 having a thermal resistance of between approximately 10 K/W and approximately 20 K/W.

24. A method of forming a thermoelectric generator, comprising the steps of:
providing a substrate;
forming metal bridges on the substrate;
forming alternating n-type and p-type legs on the substrate to form a row of thermoelectric legs such that ends of the n-type and p-type legs overlap the metal bridges to electrically interconnect the n-type and p-type legs in series, each one of the thermoelectric legs defining a leg axis oriented in non-parallel relation to the row axis; and
covering the substrate, metal bridges and n-type and p-type legs with an electrically insulating layer.

25. The method of claim 24 further comprising the step of:
connecting a top plate and a bottom plate to the substrate using thermally conductive strips aligned with opposite leg ends of the thermoelectric legs in a manner to form thermal gaps between the substrate, thermoelectric legs and top and bottom plates.

26. The method of claim 24 wherein:
the alternating n-type and p-type legs defining a row of the thermoelectric legs;
each one of the thermoelectric legs defining a leg axis;
the leg axes of the thermoelectric legs being oriented in substantially perpendicular relation to the row axis.

27. The method of claim 24 wherein the step of forming the metal bridges on the substrate comprises:
forming a layer of tungsten onto the substrate;
forming a layer of aluminum over the tungsten; and
forming a layer of tungsten over the aluminum.

28. The method of claim 24 wherein:
the semiconductor legs are formed from a material comprising Bi₂Te₃-type semiconductor material.

29. The method of claim 24 further comprising the step of:
filling the thermal gaps with material having relatively low thermal conductivity.

30. A method of forming a foil assembly of a thermoelectric generator, comprising the steps of:
providing a substrate;
forming a row of metal legs in spaced relation to one another on the substrate;
covering the metal legs with an electrically insulating layer;
forming an opening in the electrically insulating layer at opposing leg ends of the metal legs;
forming semiconductor legs onto the substrate in alternating relation to the metal legs such that leg ends of the semiconductor legs overlap and are electrically coupled to the leg ends of the metal legs to form a zig-zag pattern of the row; and
covering the substrate, metal bridges and semiconductor legs with an electrically insulating layer.

31. The method of claim 30 further comprising the step of:
connecting a top plate and a bottom plate to the substrate using thermally conductive strips aligned with opposite leg ends of the semiconductor and metal legs in a manner to form thermal gaps between the substrate, semiconductor legs and top and bottom plates causing heat to flow lengthwise through the semiconductor and metal legs.

32. The method of claim 30 wherein each one of the semiconductor and metal legs defines a leg axis, the method further comprising the step of:
forming at least one of the semiconductor and metal legs at an orientation such that the leg axes of adjacent pairs of the semiconductor and metal legs define an acute angle.

33. The method of claim 30 wherein:
the metal legs are formed of at least one of the following materials: tungsten, chromium, gold, nickel, aluminum, silver, copper, titanium, molybdenum, tantalum, doped silicon carbide;
the semiconductor legs being formed from a material comprising Bi₂Te₃-type semiconductor material.

34. The method of claim 30 further comprising the step of:
filling the thermal gaps with material having relatively low thermal conductivity.
